(19) United States
(12) Patent Application Publication
(10) Pub. No.: US 2008/0173560 A1
(43) Pub. Date: Jul. 24, 2008

(54) Glass Substrate Storage Case, Glass Substrate Transfer Apparatus, Glass Substrate Management Apparatus, Glass Substrate Distribution Method , Sealing Member, And Sealing Structure

(76) Inventors: Toshiya Umeda, Tokyo (JP); Atsushi Osada, Yamanashi (JP); Hideaki Kawashima, Tokyo (JP); Tsutomu Yoshida, Nara (JP)

Correspondence Address: MORGAN LEWIS & BOCKIUS LLP, 1111 PENNSYLVANIA AVENUE NW, WASHINGTON, DC, 20004, US

(21) Appl. No.: 11/662,266

(22) PCT Filed: Sep. 9, 2005
(86) PCT No.: PCT/JP05/16670

§ 371 Date: Sep. 26, 2007

(30) Foreign Application Priority Data
Sep. 10, 2004 (JP) 2004-264309
Jun. 7, 2005 (JP) 2005-167481

(51) Int. Cl. B65D 85/38; B07C 5/342; H01L 21/02

(52) U.S. Cl. 206/316.1; 209/558

(57) ABSTRACT

To provide a glass substrate storage case capable of preventing quality deterioration of a glass substrate, a glass substrate transfer apparatus automatically transferring a glass substrate from the glass substrate storage case to another case; a glass substrate management apparatus managing glass substrates individually, a glass substrate distribution method for trading a glass substrate while storing the glass substrate in a specialized glass substrate storage case, a sealing member improving a sealing effect, and a sealing structure using the sealing member.

The glass substrate storage case includes: a bottom member 12 on which a reticle R is placed; a cover member 20 overlaid on the bottom member 12 so as to cover the reticle R placed on the bottom member 12 and to form a space portion between the cover member 20 and the bottom member 12; a sealing member 18 provided in the bottom member 12 and/or the cover member 20 to keep the space portion airtight in a state where the cover member 20 is overlaid on the bottom member 12; and hook members 24 provided on the cover member 20 and hooked to the bottom member 12 to maintain the state where the cover member 20 is overlaid on the bottom member 12.

### TECHNICAL FIELD

The present invention relates to a glass substrate storage case storing a glass substrate such as a reticle, a glass substrate transfer apparatus transferring a glass substrate stored in the glass substrate storage case to another stepper case, a glass substrate management apparatus including the glass substrate transfer apparatus and managing glass substrates individually, a glass substrate distribution method for distributing and trading a glass substrate, a sealing member capable of improving a sealing effect, and a sealing structure using the sealing member.

### BACKGROUND ART

To manufacture a semiconductor device by photolithography, a stepper that projects and transfers a pattern pre-formed on a reticle onto a semiconductor wafer is used. Manufacturing a semiconductor device requires the exposure of different patterns by using a plurality of reticles, and thus requires a large number of reticles for the individual kinds of semiconductor devices. Therefore, a library for keeping a large number of reticles therein is disposed near the stepper.

Here, in order to prevent dust from adhering to the reticle and a person from directly touching the reticle during the course until the reticle is transported to the stepper, the reticle is handled in a state where it is put in reticle storage cases. Specifically, when a reticle is traded from a reticle maker where the reticle is manufactured to a pattern plotter where a predetermined pattern is formed on the reticle, the reticle is put in, for example, a reticle storage case having an upper cover and a lower cover and made airtight with a tape being stuck on a boundary (sticking margin) of the upper cover and the lower cover. Further, after the predetermined pattern is formed on the reticle by the pattern plotter, the reticle is put in another reticle storage case and traded to a device maker where the pattern formed on the reticle is projected and transferred onto semiconductor wafers by using a stepper. Further, in the device maker, the reticle is put in a reticle storage case specialized for reticle storage and the reticle storage case housing the reticle is kept in a library in a clean room.

As descried above, the reticle is put in different reticle storage cases of various kinds in a trading process from the reticle maker to the pattern plotter (hereinafter, referred to as “a first trading process” when appropriate), in a trading process from the pattern plotter to the device maker (hereinafter, referred to “a second trading process” when appropriate), and in a storage process in the device maker.

[Patent document 1]

Japanese Patent Application Laid-open No. 2000-269301

### DISCLOSURE OF THE INVENTION

### Problems to be Solved by the Invention

Since the reticle is transferred to different reticle storage cases in the first trading process, the second trading process, and the storage process, it is necessary to prepare reticle storage cases in the respective processes, which is a great burden to each maker and trader. Moreover, since no sufficiently hermetic storage case has been available, a tape was wound around a sticking margin of a lower cover and an upper cover of a reticle storage case for ensuring airtightness when the reticle is taken out of the clean room (the first trading process, the second trading process), resulting in poor workability. In addition, during this work, a slight air flow occurs in the reticle storage case, which may possibly cause the adhesion of dusts and the like to the reticle.

The use of a rubber sealing member to seal a semiconductor or reticle storage container for ensuring airtightness has been proposed (Japanese Patent Application Laid-open No. 2005-31489).

However, if a typical sealing member with a circular cross section, an elliptic cross section, a square cross section, or the like as proposed here is used, the sealing member has to be crushed with a strong load in order to make elastic deformation necessary for realizing airtightness. When given a compression reactive force caused by such elastic deformation of the sealing member, a reticle storage container, which is made of a relatively thin resin material and is not very stiff, cannot resist the reactive force, resulting in a problem that the container itself is warped to easily cause poor sealing.

Further, to automate a work of opening/closing a storage container, a container whose main body and cover can be opened/closed with a smaller force is desirable, and a sealing member that can realize airtightness with a low load is desired.

Further, the library, which is disposed near the stepper to keep the reticles therein, has to be provided inside a clean room. This results not only in an increase in size of the stepper but also in cost increase due to a great increase in equipment expenses for providing the clean room.

In view of the above circumstances, it is an object of the present invention to provide a glass substrate storage case capable of ensuring airtightness and preventing quality deterioration of a glass substrate such as a reticle during the distribution of the glass substrate, a glass substrate transfer apparatus automatically transferring a glass substrate from the glass substrate storage case to another storage case, a glass substrate management apparatus including the glass substrate transfer apparatus and individually managing glass substrates, thereby enabling size reduction and cost reduction of a stepper, a glass substrate distribution method enabling the trading of a glass substrate from a glass substrate maker to a device maker, by using the specialized glass substrate storage case storing the glass substrate, a sealing member capable of improving a sealing effect, and a sealing structure using the sealing member.

### Means to Solve the Problems

An invention according to claim 1 is a glass substrate storage case for storing a glass substrate, including: a bottom member on which the glass substrate is placed; a cover member overlaid on the bottom member so as to cover the glass substrate placed on the bottom member and to form a space portion between the bottom member and the cover member; a sealing member provided in the bottom member and/or the cover member to keep the space portion airtight in a state where the cover member is overlaid on the bottom member; and a hook member provided on the cover member and hooked to the bottom member to maintain the state where the cover member is overlaid on the bottom member.

An invention according to claim 2 is the glass substrate storage case according to claim 1, wherein the hook member has: a shaft rotatably provided on the cover member; and a claw portion rotating with respect to the shaft as a rotation axis to be engaged with a bottom portion of the bottom member.

An invention according to claim 3 is the glass substrate storage case according to claim 1 or 2, wherein the sealing member is disposed in a groove formed in the cover member and/or the bottom member, wherein the sealing member has: a pair of pressure portions inserted in the groove to press sidewalls of the groove; and a bent portion connecting the pressure portions and coming in contact with the cover member or the bottom member to elastically deform when the cover member is overlaid on the bottom member, and wherein a thickness of the pressure portions is larger than a thickness of the bent portion.

An invention according to claim 4 is the glass substrate storage case according to claim 3, wherein projections are provided on at least part of areas from the bent portion to the pressure portions.

An invention according to claim 5 is the glass substrate storage case according to claim 4, wherein thickness gradually becomes larger from the bent portion toward the pressure portions.

An invention according to claim 6 is the glass substrate storage case according to claim 1 or 2, wherein a groove having a salient portion is formed in the cover member and/or the bottom member, wherein the sealing member is made of rubber, and wherein the sealing member has: a pair of pressure portions inserted in the groove so as to sandwich the salient portion and pressing groove sidewalls facing the salient portion; and a thin portion which connects the pressure portions and whose portion that comes in contact with the cover member or the bottom member when the cover member is overlaid on the bottom member is formed in a curved shape and elastically deforms by coming in contact with the cover member or the bottom member when the cover member is overlaid on the bottom member.

An invention according to claim 7 is the glass substrate storage case according to claim 6, wherein a thickness of the thin portion is not less than 0.2 mm nor more than 0.6 mm.

An invention according to claim 8 is the glass substrate storage case according to claim 6 or 7, wherein a thickness of each of the pressure portions gradually becomes smaller toward a tip portion that is in contact with a bottom of the groove.

An invention according to claim 9 is the glass substrate storage case according to any one of claims 6 to 8, wherein the sealing member is formed symmetrical with respect to a center line extending in a height direction of a cross section taken along a thickness direction of the sealing member.

An invention according to claim 10 is a glass substrate transfer apparatus transferring a glass substrate stored in the glass substrate storage case according to any one of claims 1 to 9 into another stepper case, the apparatus including: a lift member which is movable up/down and on which the glass substrate storage case is placed; an engagement release member releasing the hooking of the hook member to the bottom member of the glass substrate storage case placed on the lift member and supporting the cover member from under; a base member on which the stepper case is placed; and an arm member taking out, from the bottom member, the glass substrate placed on the bottom member on the lift member to move the glass substrate to the stepper case side.

An invention according to claim 11 is the glass substrate transfer apparatus according to claim 10, wherein the engagement release member includes: a pressing portion pressing the cover member against the bottom member to elastically deform the sealing member, thereby releasing the engagement of the claw member and the bottom member; and a release/support portion lifting the claw portion disengaged from the bottom member while rotating the claw portion with respect to the shaft, and supporting the cover member.

An invention according to claim 12 is a glass substrate management apparatus managing glass substrates, the apparatus including: the glass substrate transfer apparatus according to claim 10 or 11; and a stock room formed under a floor on which the glass substrate transfer apparatus is installed.

An invention according to claim 13, wherein by using the glass substrate storage case according to any one of claims 1 to 9, the glass substrate is distributed from a glass substrate maker manufacturing the glass substrate to a pattern plotter forming a predetermined pattern on the glass substrate and further from the pattern plotter to a device maker projecting/transferring the pattern on the glass substrate onto a semiconductor wafer.

An invention according to claim 14 is a sealing member made of an elastic material and fitted in a groove formed in a joint surface between members, the sealing member including: a pair of pressure portions pressing sidewalls of the groove when the sealing member is fitted in the groove; and a bent portion connecting the pair of pressure portions to each other, wherein, to fit the sealing member in the groove, a distance between the pressure portions is reduced.

An invention according to claim 15 is the sealing member according to claim 14, wherein a thickness of the sealing member gradually becomes larger from the bent portion toward the pressure portions

An invention according to claim 16 is the sealing member according to claim 14 or 15, wherein projections are provided on at least part of areas between the bent portion and the pressure portions.

An invention according to claim 17 is a sealing member made of rubber and fitted in a groove formed in a joint surface between members so as to sandwich a salient portion of the groove, the sealing member including: a pair of pressure portions pressing groove sidewalls facing the salient portion while the sealing member is inserted in the groove; and a thin portion which connects the pressure portions and whose portion that comes in contact with one or the other of the members is formed in a curved shape and elastically deforms by coming in contact with one or the other of the members.

An invention according to claim 18 is the sealing member according to claim 17, wherein a thickness of the thin portion is not less than 0.2 mm nor more than 0.6 mm.

An invention according to claim 19 is the sealing member according to claim 17 or 18, wherein a thickness of each of the pressure portions gradually becomes smaller toward a tip portion that is in contact with a bottom of the groove.

An invention according to claim 20 is the sealing member according to any one of claims 17 to 19, the sealing member being formed symmetrical with respect to a center line extending in a height direction of a cross section taken along a thickness direction of the sealing member.

An invention according to claim 21 is a sealing structure for realizing sealing by the sealing member according to any one of claims 14 to 20 fitted in the groove, wherein an opening edge of the groove is chamfered so as to widen an opening of the groove.

### EFFECT OF THE INVENTION

According to the invention as set forth in claim 1, the glass substrate is placed on the bottom member, and the cover member is overlaid on the bottom member. As a result, the space portion is formed between the cover member and the bottom member, and the glass substrate is stored in the space portion.

Here, since the sealing member is provided in the bottom member and/or the cover member, the sealing member is pressed by the both members to elastically deform, so that the space portion becomes airtight in the state where the cover member is overlaid on the bottom member. This prevents the adhesion of dusts and the like to the glass substrate put therein, resulting in no quality deterioration of the glass substrate. Further, since the hook member is provided on the cover member, it is possible to maintain the airtight state by hooking the hook member to the bottom member. As a result, in order to allow the glass substrate to be freely distributed/traded, it is only necessary to put the glass substrate in the glass substrate storage case.

It is possible to easily detach the cover member from the bottom member by releasing the hooking of the hook member to the bottom member. Consequently, the glass substrate can be taken out from the glass substrate storage case.

According to the invention as set forth in claim 2, when the cover member is overlaid on the bottom member, the claw portion rotates with respect to the shaft as the rotation axis to be engaged with the bottom portion of the bottom member. Thus, the hook member can have a simple structure and the airtightness can be surely maintained.

According to the invention as set forth in claim 3, the pressure portions of the sealing member are inserted in the groove to press the sidewalls of the groove, and the bent portion of the sealing member connects the pressure portions to each other and comes in contact with the cover member or the bottom member to elastically deform when the cover member is overlaid on the bottom member. This can make the space portion airtight.

Here, since the thickness of the pressure portions is larger than the thickness of the bent portion, a pressure acting on the sidewalls of the groove from the pressure portions can be made large, and a pressure acting on the cover member or the bottom member from the bent portion can be made small. Consequently, the sealing member is surely prevented from coming off the groove, and the pressure (elastic force, repulsive force) acting on the cover member or the bottom member from the sealing member when the cover member is overlaid on the bottom member can be made relatively small, so that breakage of the cover member or the bottom member can be prevented even if the cover member or the bottom member is made of a specific material (for example, resin).

Further, the pressure portions, if having a relatively large thickness, can have improved stiffness, and are not easily deformed when the pressure acts on the bent portion from the cover member or the bottom member. This can prevent the pressure portions from sliding on the sidewalls of the groove, so that no frictional force occurs between the pressure portions and the sidewalls of the groove, which can prevent the occurrence of damage such as cracks in the pressure portions.

According to the invention as set forth in claim 4, the projections are provided on at least part of the areas between the bent portion and the pressure portions, so that it is possible to easily hold the sealing member by gripping the projections. This can improve easiness in handling the sealing member, and therefore, for example, the insertion of the sealing member in the groove can be facilitated.

According to the invention as set forth in claim 5, the sealing member gradually becomes thicker from the bent portion toward each of the pressure portions, so that the thickness of each of the pressure portions can be more effectively made larger than the thickness of the bent portion. In particular, owing to the gradual increase of the thickness from the bent portion toward each of the pressure portions, the areas between the bent portion and the pressure portions can be free of a stress concentrated portion, which can prevent strength deterioration of the sealing member, resulting in improved durability thereof.

According to the invention as set forth in claim 6, the pressure portions of the sealing member press the sidewalls of the groove while inserted in the groove, and the thin portion of the sealing member connects the pressure portions to each other and comes in contact with the cover member or the bottom member to elastically deform when the cover member is overlaid on the bottom member. This can make the space portion airtight.

Here, when the cover member is overlaid on the bottom member, the thin portion comes in contact with the cover member or the bottom member to elastically deform, so that the space portion can be kept airtight. Further, since the thin portion is made of rubber, even when the thin portion elastically deforms when coming in contact with the cover member or the bottom member, a compression reactive force acting on the cover member or the bottom member from the thin portion can be reduced, so that the occurrence of warp or the like of the cover member or the bottom member can be prevented. Further, since the portion that comes in contact with the cover member or the bottom member when the cover member is overlaid on the bottom member is formed in a curved shape, the thin portion slides little on the cover member or the bottom member, as contrast to, for example, a conventional sealing member having a lip piece, so that the occurrence of particles ascribable to the friction with the cover member or the bottom member can be prevented.

According to the invention as set forth in claim 7, since the thickness of the thin portion is not less than 0.2 mm nor more than 0.6 mm, airtightness of the space portion can be ensured, and the compression reactive force acting on the cover member or the bottom member from the thin portion can be made small, which can prevent the occurrence of warp or the like of the cover member or the bottom member. As described above, the airtightness of the space portion and the prevention of the occurrence of the warp of the cover member or the bottom member can be both ensured.

On the contrary, if the thickness of the thin portion is more than 0.6 mm, the compression reactive force acting on the cover member or the bottom member from the thin portion becomes large, which poses a problem of easy occurrence of warp or the like of the cover member or the bottom member. If the thickness of the thin portion is less than 0.2 mm, the thin portion itself lacks stiffness and a repulsive force, and as a result, the compression reactive force acting on the cover member or the bottom member becomes too small, which has a problem that the airtightness of the space portion cannot be ensured.

According to the invention as set forth in claim 8, the thickness of each of the pressure portions gradually becomes smaller toward the tip portion that is in contact with the bottom surface of the groove, which can facilitate inserting the sealing member in the groove.

According to the invention as set forth in claim 9, the sealing member is formed symmetrical with respect to the center line extending in the height direction of the cross section taken along the thickness direction of the sealing member, so that the thin portion slides little on the cover member or the bottom member when the thin portion comes in contact with the cover member or the bottom member, which can effectively reduce the occurrence of particles.

According to the invention as set forth in claim 10, the glass substrate storage case is placed on the lift member and the engagement release member releases the hooking of the hook member to the bottom member. At this time, the cover member is supported by the engagement release member from under. When the lift member moves down while the engagement release member has released the hooking of the hook member to the bottom member and is supporting the cover member from under, the cover member is detached from the bottom member and only the bottom member placed on the lift member moves down with the lift member. At this time, the glass substrate is in an exposed state. Next, the arm member takes out the exposed glass substrate from the bottom member, and moves the glass substrate to the stepper case side placed on the base member.

The glass substrate transferred to the stepper case is sent to a stepper, where a predetermined pattern formed on the glass substrate is projected/transferred onto a semiconductor wafer.

As described above, the glass substrate transfer apparatus is capable of easily transferring the glass substrate from the glass substrate storage case to the stepper case.

According to the invention as set forth in claim 11, when the glass substrate storage case is placed on the lift member, the cover member is pressed against the bottom member by the pressing portion. Consequently, the sealing member elastically deforms and a relative distance between the cover member and the bottom member is reduced, so that the engagement of the claw portion and the bottom member is released. The release/support portion lifts up the claw portion disengaged from the bottom member while rotating the claw portion with respect to the shaft. Further, when the claw portion is supported by the release/support portion, the cover member is supported by the release/support portion. In this manner, the engagement release member can have a simple structure, and the engagement between the claw portion and the bottom portion can be easily released. Moreover, since the cover member is supported by the release/support portion, it is possible to easily detach the cover member from the bottom member by moving the bottom member downward.

According to the invention as set forth in claim 12, since the stock room is formed under the floor on which the glass substrate transfer apparatus is installed, an effective use of the space under the floor is possible. This can eliminate a dead space of a room (for example, a clean room) where the glass substrate transfer apparatus is installed, which makes it possible to effectively use the space in the clean room for other purposes.

According to the invention as set forth in claim 13, by using the glass substrate storage case according to any one of claims 1 to 9, the glass substrate is distributed from a glass substrate maker manufacturing the glass substrate to a pattern plotter forming a predetermined pattern on the glass substrate, and further from the pattern plotter to a device maker projecting/transferring the pattern on the glass substrate onto semiconductor wafers, and therefore, the same glass substrate storage case can be used. This frees the makers and traders from a need for separately preparing storage cases for storing the glass substrate.

Further, since the glass substrate is stored in the aforesaid glass substrate storage case, to enhance airtightness of the glass substrate, it is not necessary to stick a tape or the like on the glass substrate storage case as has been conventionally necessary. Therefore, to take out the glass substrate, there is no need to peel off the tape or the like stuck on the glass substrate storage case, and thus dusts and the like do not swirl in the glass substrate storage case, which can prevent quality deterioration of the glass substrate.

According to the invention as set forth in claim 14, to fit the sealing member in the groove, the distance between the pressure portions is reduced, and when the sealing member is fitted in the groove, the pressure portions press the sidewalls of the groove. This can prevent the sealing member from coming off the groove and being displaced in the groove. Further, since one of the members comes in contact with the bent portion to press the bent portion and the bent portion elastically deforms, a gap between the members can be effectively sealed.

According to the invention as set forth in claim 15, since the thickness of the sealing member gradually becomes larger from the bent portion to each of the pressure portions, the thickness of each of the pressure portions can be more effectively made larger than the bent portion. In particular, owing to the gradual increase of the thickness from the bent portion toward each of the pressure portions, the areas between the bent portion and the pressure portions can be free of a stress concentrated portion, which can prevent strength deterioration of the sealing member, resulting in improved durability thereof.

According to the invention as set forth in claim 16, since the projections are provided on at least part of the areas between the bent portion and the pressure portions, it is possible to easily hold the sealing member by gripping the projections. This can improve easiness in handling the sealing member, and can facilitate, for example, the fitting of the sealing member in the groove.

According to the invention as set forth in claim 17, the pressure portions of the sealing member are inserted in the groove to press the sidewalls of the groove, and the thin portion of the sealing member connects the pressure portions and comes in contact with one of the members to elastically deform when one of the members is overlaid on the other. This can make the space portion airtight.

Here, when one of the members is overlaid on the other, the thin portion comes in contact with one or the other of the members to elastically deform, which makes it possible to keep the space portion formed in one or the other of the members airtight. Further, since the thin portion is made of rubber, a compression reactive force acting on one or the other of the members from the thin portion can be made small even when the thin portion elastically deforms when coming in contact with one or the other of members, and the occurrence of warp or the like of one or the other of the members can be prevented. Further, since the portion which comes in contact with one or the other of the members when one of the members is overlaid on the other is formed in the curved shape, the thin portion slides little on one or the other of the members, as contrast to, for example, a conventional sealing member having a lip piece, and therefore, the occurrence of particles ascribable to the friction with one or the other of the members can be prevented.

According to the invention as set forth in claim 18, since the thickness of the thin portion is not less than 0.2 mm nor more than 0.6 mm, airtightness of the space portion formed in one or the other of the members can be ensured, and the compression reactive force acting on one or the other of the members from the thin portion can be reduced, which can prevent the occurrence of warp or the like of one or the other of the members. In this manner, the airtightness of the space portion formed in one or the other of the members and the prevention of the occurrence of the warp or the like of one or the other of the members can both be ensured.

On the contrary, if the thickness of the thin portion is more than 0.6 mm, the compression reactive force acting on the cover member or the bottom member from the thin portion becomes large, which poses a problem of easy occurrence of warp or the like of the cover member or the bottom member. If the thickness of the thin portion is less than 0.2 mm, the thin portion itself lacks stiffness and a repulsive force, and as a result, the compression reactive force acting on the cover member or the bottom member becomes too small, which has a problem that the airtightness of the space portion cannot be ensured.

According to the invention as set forth in claim 19, the thickness of each of the pressure portions gradually becomes smaller toward the tip portion that is in contact with the bottom surface of the groove, which can facilitate inserting the sealing member in the groove.

According to the invention as set forth in claim 20, since the sealing member is formed symmetrical with respect to the center line extending in the height direction of the cross section taken along the thickness direction of the sealing member, the thin portion slides little on one or the other of the members when coming in contact with one or the other of the members, which can effectively prevent the occurrence of particles.

According to the invention as set forth in claim 21, the sealing member is fitted in the groove formed in the joint surface between the members to seal a gap between the members. Here, since the opening edge of the groove is chamfered so as to widen the opening portion, the opening edge of the groove does not obstruct the fitting of the sealing member, so that the sealing member can be easily fitted in the groove. In particular, if the sealing member has projections, it is possible to easily fit the sealing member in the groove while gripping the projections since the opening portion is wide owing to the chamfering of the opening edge of the groove, which can greatly improve fittability of the sealing member.

Preferably, the sealing member is made of an elastic material and the engagement between the claw portion and the bottom portion of the bottom member is released by the elastic deformation of the sealing member when the cover member is pressed against the bottom member. According to this structure, when the cover member is pressed against the bottom member, the sealing member elastically deforms to release the engagement between the claw portion and the bottom portion of the bottom member. Therefore, only by pressing the cover member against the bottom member, it is possible to easily release the engagement between the claw portion and the bottom portion of the bottom member, which facilitates the work of taking out the glass substrate.

Preferably, the sealing member is disposed in the groove formed in the cover member and/or the bottom member, and the sealing member has pressure portions pressing the sidewalls of the groove when the sealing member is disposed in the groove. According to this structure, the sealing member is disposed in the groove formed in the cover member and/or the bottom member, but since at this time, the pressure portions of the sealing member press the sidewalls of the groove, it is possible to prevent the sealing member from coming off the groove and to stabilize the posture of the sealing member in the groove.

Preferably, each of the pressure portions has an overhanging portion coming in contact with the sidewall of the groove. According to this structure, since the overhanging portion coming in contact with the sidewall of the groove is formed on each of the pressure portions, it is possible to seal a gap between the sealing member and the sidewalls of the groove while the sealing member is fitted in the groove. Consequently, the entrance of foreign substances such as water and dusts into the groove can be prevented, which can prevent breakage of the sealing member, resulting in improved durability of the sealing member.

Preferably, the bottom member has a support member supporting the glass substrate while keeping the glass substrate apart from the bottom member. According to this structure, since the bottom member has the support member, the glass substrate is supported from under by the support member while being apart from the bottom member. Therefore, to take out the glass substrate supported by the support member, it is possible to lift up the glass substrate by utilizing a gap between the glass substrate and the bottom member, which can facilitate taking out the glass substrate.

Preferably, the cover member and/or the bottom member has a positioning member positioning the glass substrate. According to this structure, since the cover member and/or the bottom member has the positioning member, it is possible to position the glass substrate. Therefore, even when the glass substrate is distributed/traded while being stored in the glass substrate storage case, the glass substrate does not move in the space portion of the glass substrate storage case, which can prevent quality deterioration of the glass substrate.

Preferably, the cover member is made of transparent conductive resin. According to this structure, since the cover member is made of transparent conductive resin, it is possible to confirm the glass substrate stored inside from the outside of the glass substrate storage case without detaching the cover member from the bottom member. Further, since the cover member is made of the conductive resin, dusts and the like easily adhere to the cover member, which can prevent dusts from swirling in the space portion.

Preferably, the apparatus includes: a highly airtight first clean room where the lift member is disposed; a highly airtight second clean room provided adjacent to the first clean room, with the arm member disposed therein; a highly airtight third clean room provided adjacent to the second clean room, with the base member disposed therein; a first partition member separating the first clean room and the second clean room; a second partition member separating the second clean room and the third clean room; a first opening portion formed in the first partition member to make the first clean room and the second clean room communicate with each other; a second opening portion formed in the second partition member to make the second clean room and the third clean room communicate with each other; a first opening/closing member opening/closing the first opening portion; and a second opening/closing member opening/closing the second opening portion. According to this structure, the glass substrate on the bottom member placed on the lift member is taken out from the bottom member by the arm member while the first opening/closing portion is opening the first opening portion and the second opening/closing member is closing the second opening portion. Consequently, the glass substrate moves from the first clean room to the second clean room. At this time, the first clean room and the second clean room come to communicate with each other, but since the first clean room and the second clean room are highly airtight and the second opening portion is closed and thus no air flow occurs, it is possible to prevent the adhesion of dusts and the like to the glass substrate. Next, the glass substrate taken out by the arm member is transferred to a stepper case placed on the base member in the third clean room while the first opening/closing means is closing the first opening portion and the second opening/closing means is opening the second opening portion. At this time, the second clean room and the third clean room come to communicate with each other, but since the second clean room and the third clean room are highly airtight and the first opening portion is closed and thus no air flow occurs, it is possible to prevent the adhesion of dusts and the like to the glass substrate. As described above, performing a transfer work of the glass substrate in each of the clean rooms can prevent the adhesion of dusts and the like to the glass substrate and thus can prevent quality deterioration of the glass substrate.

Preferably, an elastic member is attached to the pressing portion, and the pressing portion presses the cover member against the bottom member via the elastic member. According to this structure, since the elastic member is attached to the pressing portion and the pressing portion presses the cover member against the bottom member via the elastic member, breakage of the cover member can be prevented.

Preferably, the glass substrate management apparatus managing glass substrates includes: the glass substrate transfer apparatus according to any one of claims 12 to 15; and a stock room provided near the glass substrate transfer apparatus and storing the plural glass substrates, each being stored in the glass substrate storage case. According to this structure, near the glass substrate transfer apparatus, there is provided the stock room storing the plural glass substrates, each being stored in the glass substrate storage case, and therefore, to transfer the glass substrate by the glass substrate transfer apparatus from the glass substrate storage case to the stepper case, a necessary one of the glass substrates can be quickly and easily taken out from the stock room. Further, a large library for storing the glass substrates need not be provided in the stepper, which can make the stepper compact and greatly reduce manufacturing cost of the stepper. Incidentally, an unnecessary glass substrate can be stored in the stock room after stored in the glass substrate storage case.

Preferably, an opening portion is formed in the floor, a standby room connected to the opening portion is disposed near the first clean room, and the apparatus has a transfer means for transferring the glass substrate storage case storing the glass substrate from the stock room to the standby room or from the standby room to the stock room. According to this structure, after the glass substrate storage case storing the necessary glass substrate is placed on the transfer means, the transfer means moves from the stock room to the standby room via the opening portion. Consequently, the necessary glass substrate can be taken out from the stock room. The glass substrate transferred to the standby room is placed on the lift member while being stored in the glass substrate storage case, and then transferred to another stepper case. On the other hand, an unnecessary glass substrate is stored in the glass substrate storage case and thereafter placed on the transfer means to be transferred by the transfer means from the standby room to the stock room via the opening portion. Then, it is kept in the stock room while being stored in the glass substrate storage case.

Preferably, the apparatus includes: a determining means for recognizing an ID number of the glass substrate stored in the glass substrate storage case and an ID number of the glass substrate to determine whether or not the both match each other; and a display means for displaying a result of the determination by the determination means. According to this structure, the determination means recognizes the ID number of the glass substrate stored in the glass substrate storage case and the ID number of the glass substrate storage case and determines whether or not the both match each other. The determination result is displayed by the display means. This allows a user to instantaneously determine whether or not the glass substrate and the glass substrate storage case match each other only by checking the display means. As a result, it is possible to keep the glass substrate in a state where the glass substrate and the glass substrate storage case match each other, which can enhance a function of managing the glass substrates.

Preferably, a thickness of the pressure portions is larger than a thickness of the bent portion. According to this structure, since the thickness of the pressure portions is larger than the thickness of the bent portion, a pressure acting on the sidewalls of the groove from the pressure portions can be increased, and a pressure acting on the member in contact with the bent portion from the bent portion can be reduced. Consequently, the sealing member is surely prevented from coming off the groove, and a pressure (elastic force, repulsive force) acting from the sealing member on the member which comes in contact with the sealing member when the members are joined together can be made small, so that breakage of the member can be prevented even if the member is made of a specific material (for example, resin). Further, the pressure portions, if having a relatively large thickness, can have improved stiffness, and are not easily deformed when the pressure acts on the bent portion from the member in contact with the bent portion. This can prevent the deformation of the pressure portions. Consequently, it is possible to prevent the pressure portions from sliding on the sidewalls of the groove, so that no frictional force occurs between the pressure portions and the sidewalls of the groove, which can prevent the occurrence of damage such as cracks in the pressure portions.

Preferably, each of the pressure portions has an overhanging portion coming in contact with the sidewall of the groove. According to this structure, since the overhanging portion coming in contact with the sidewall of the groove is formed on each of the pressure portions, it is possible to seal a gap between the sealing member and the sidewalls of the groove while the sealing member is fitted in the groove. Consequently, the entrance of foreign substances such as water and dusts into the groove can be prevented, which can prevent breakage of the sealing member, resulting in improved durability of the sealing member. Further, it is possible to position the sealing member in the groove by the overhanging portion coming in contact with the sidewalls of the groove.

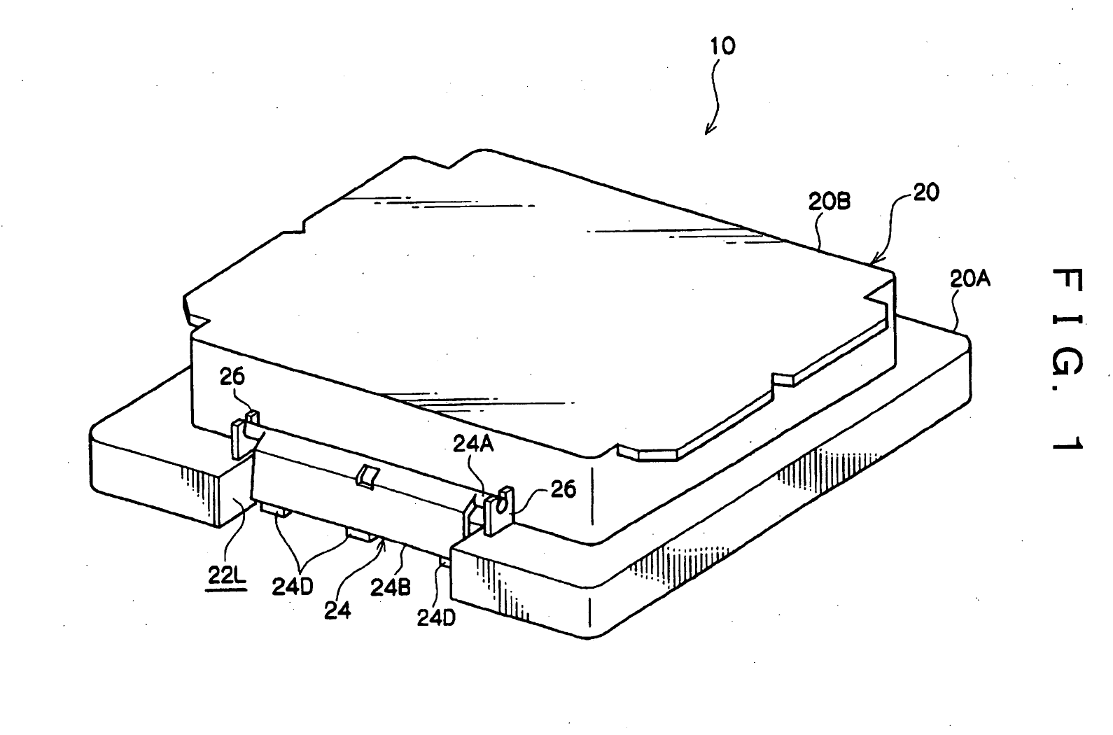

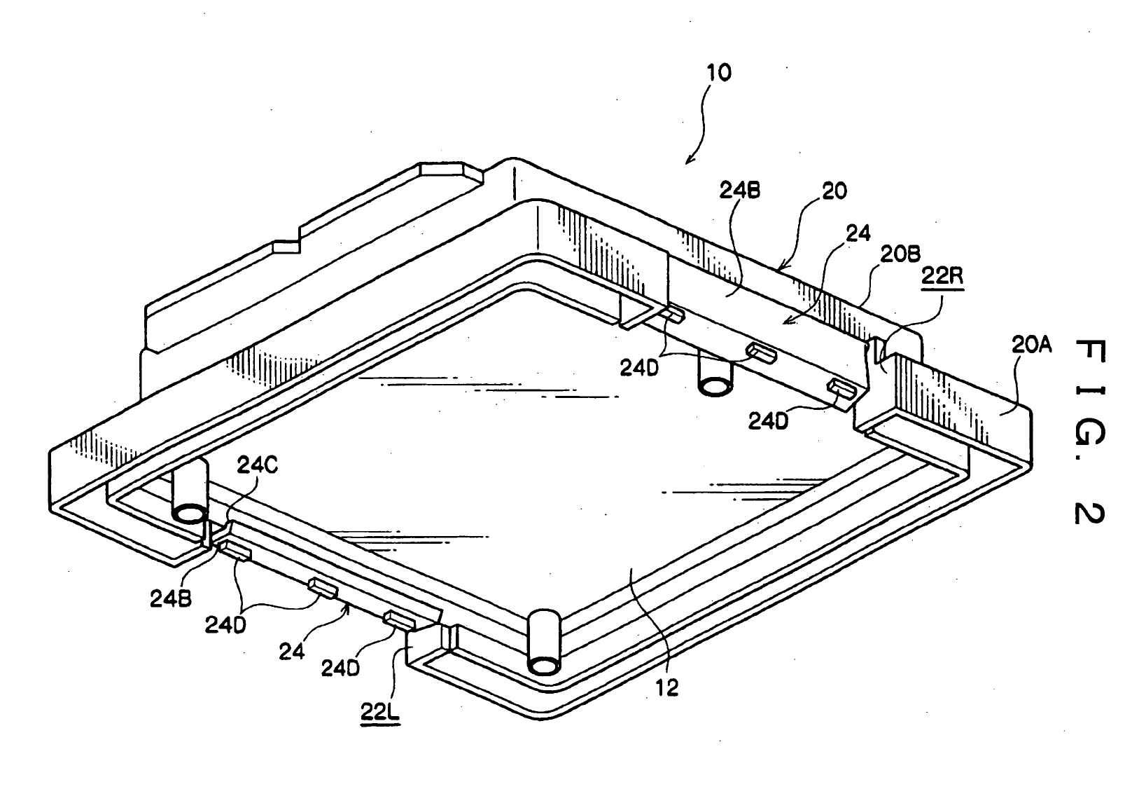

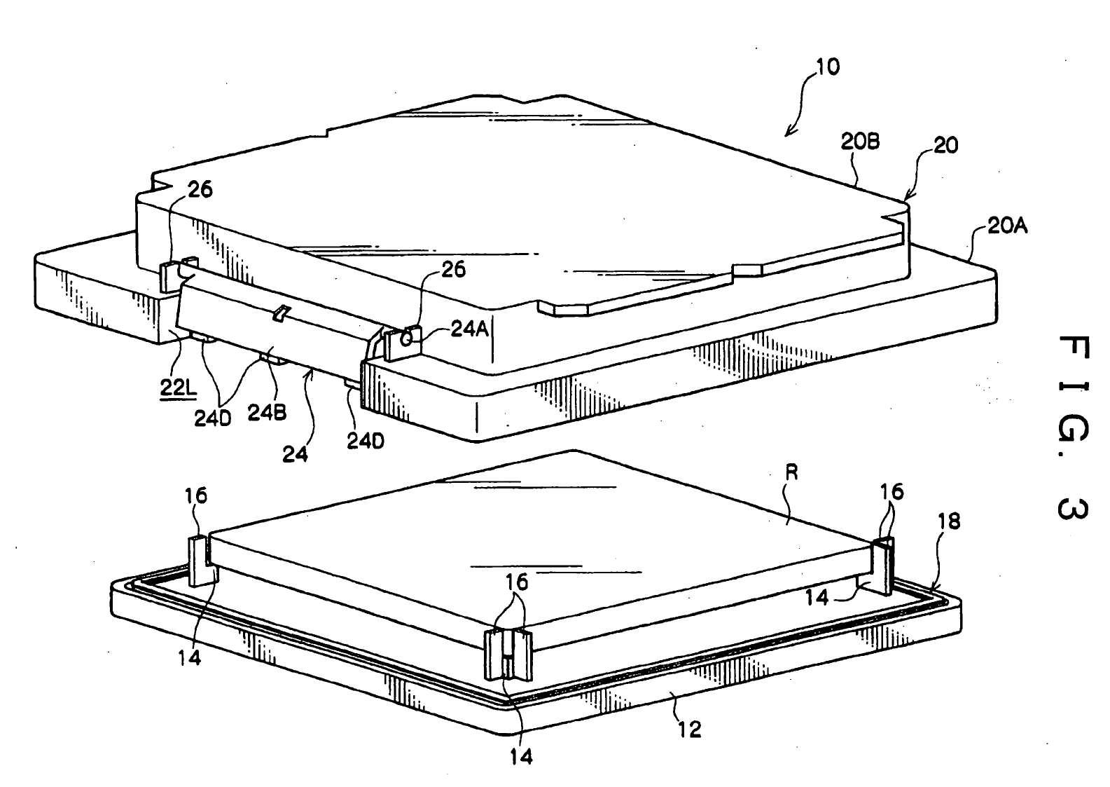

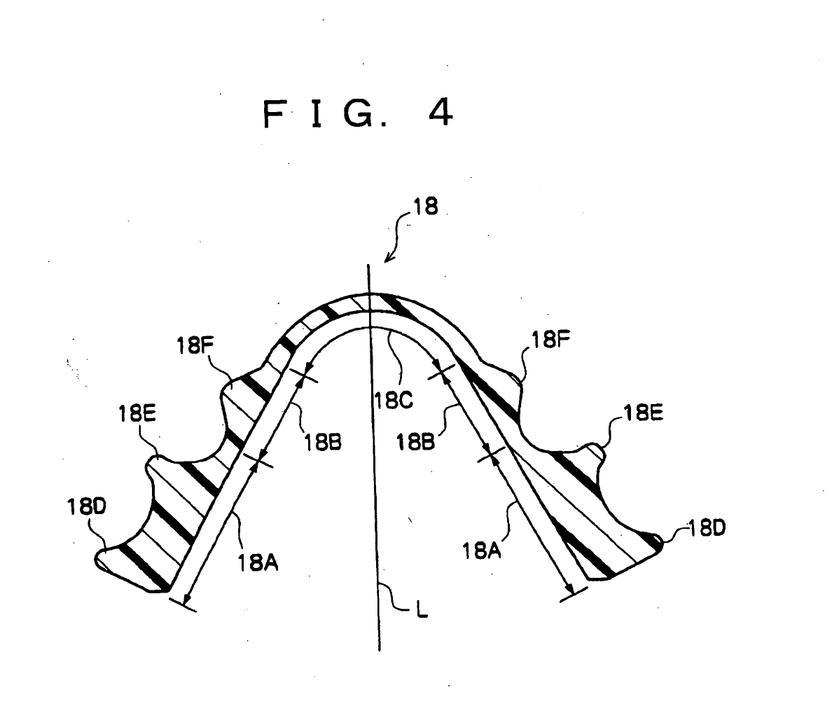

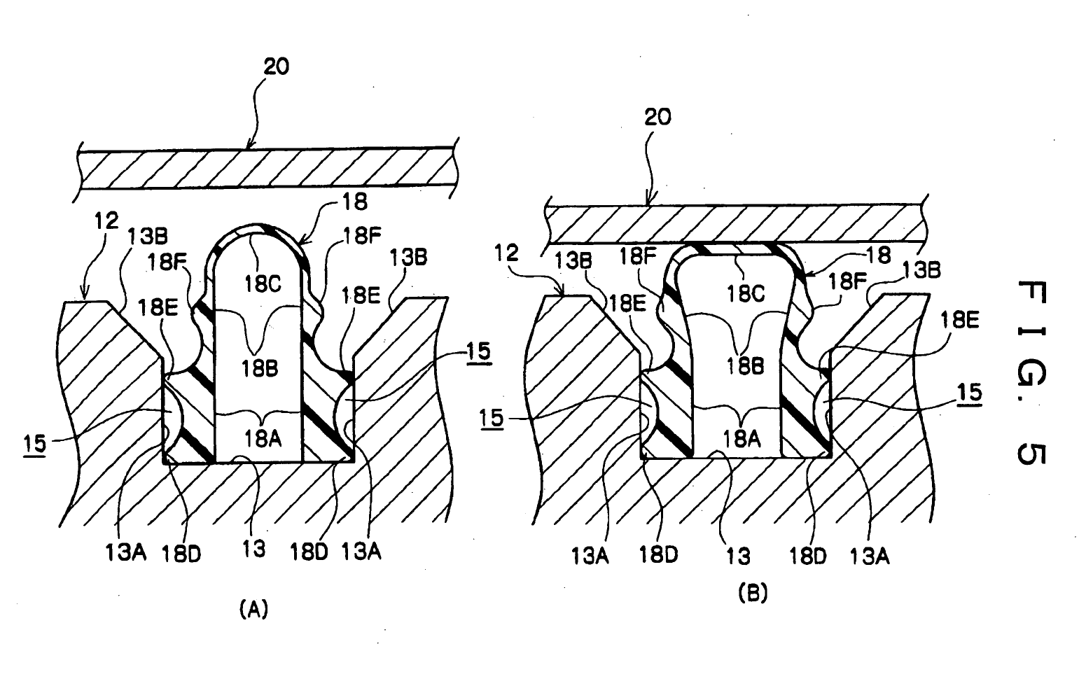

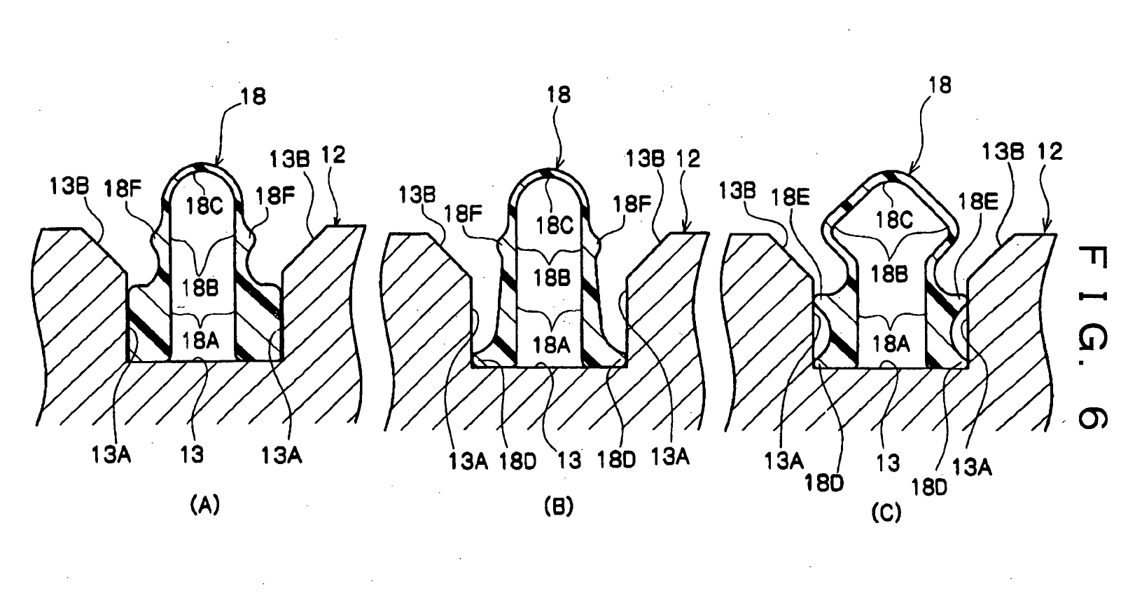

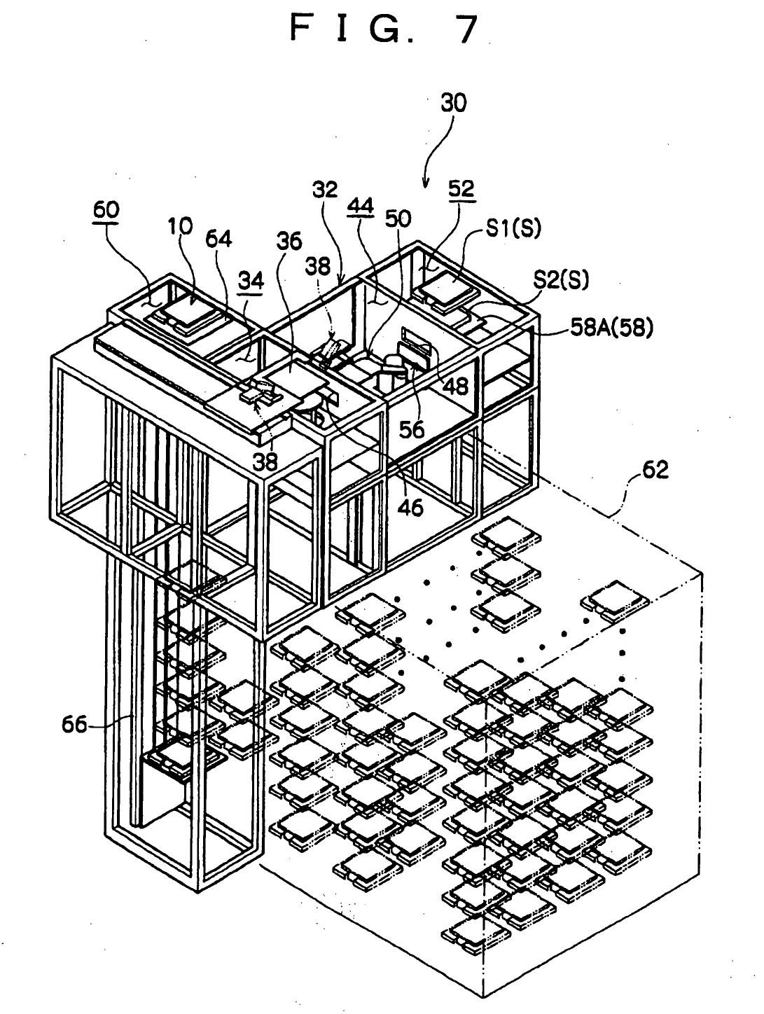

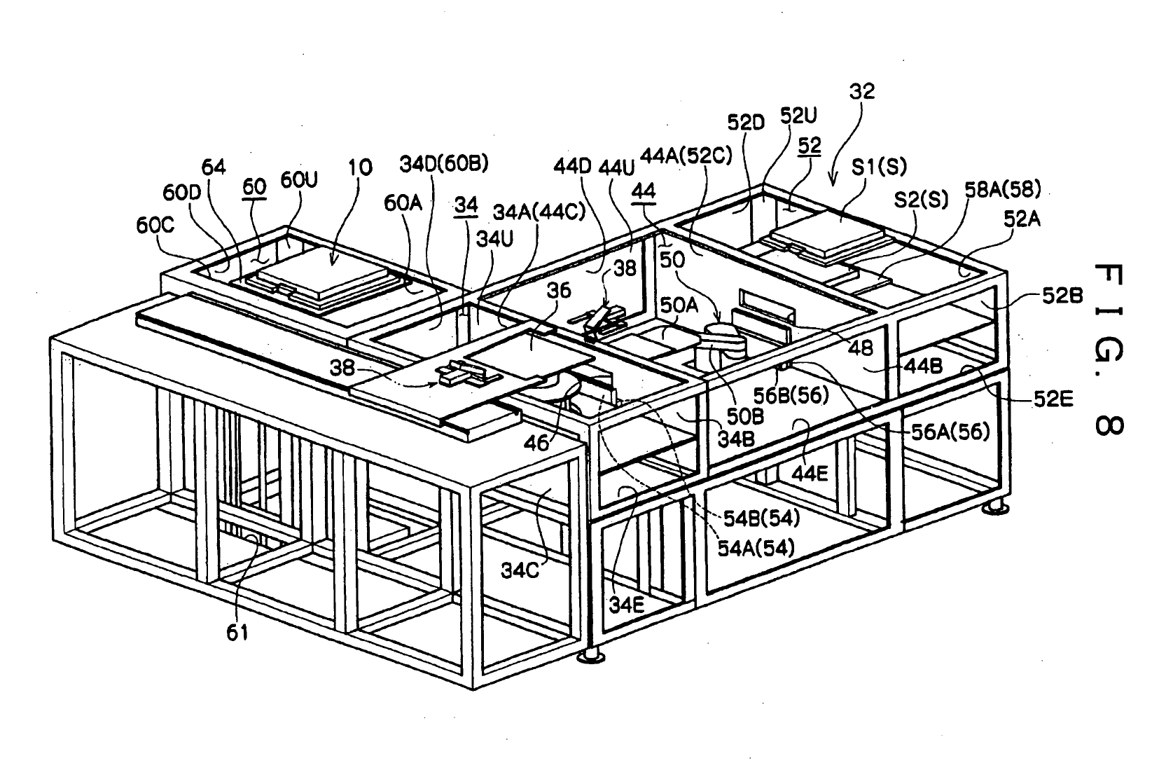

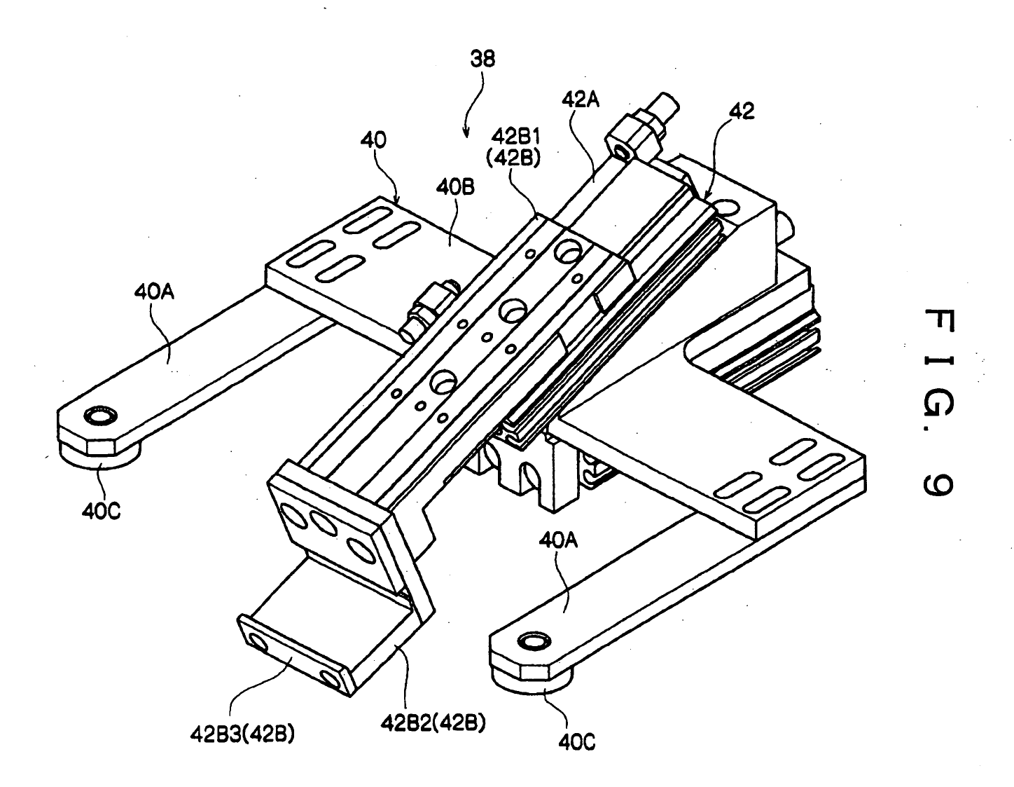

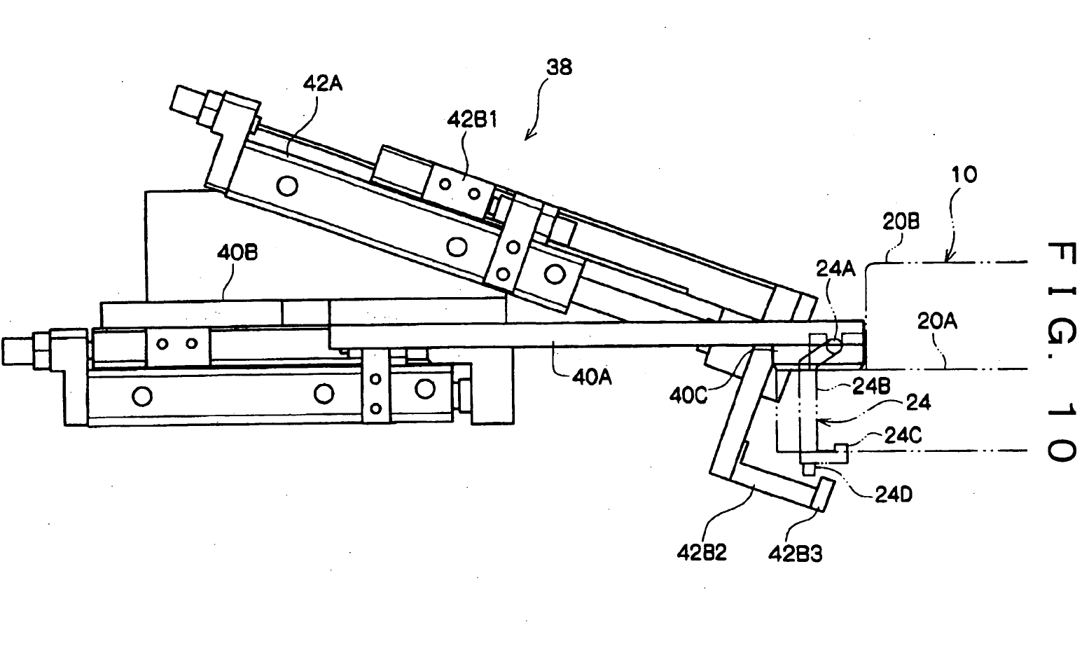

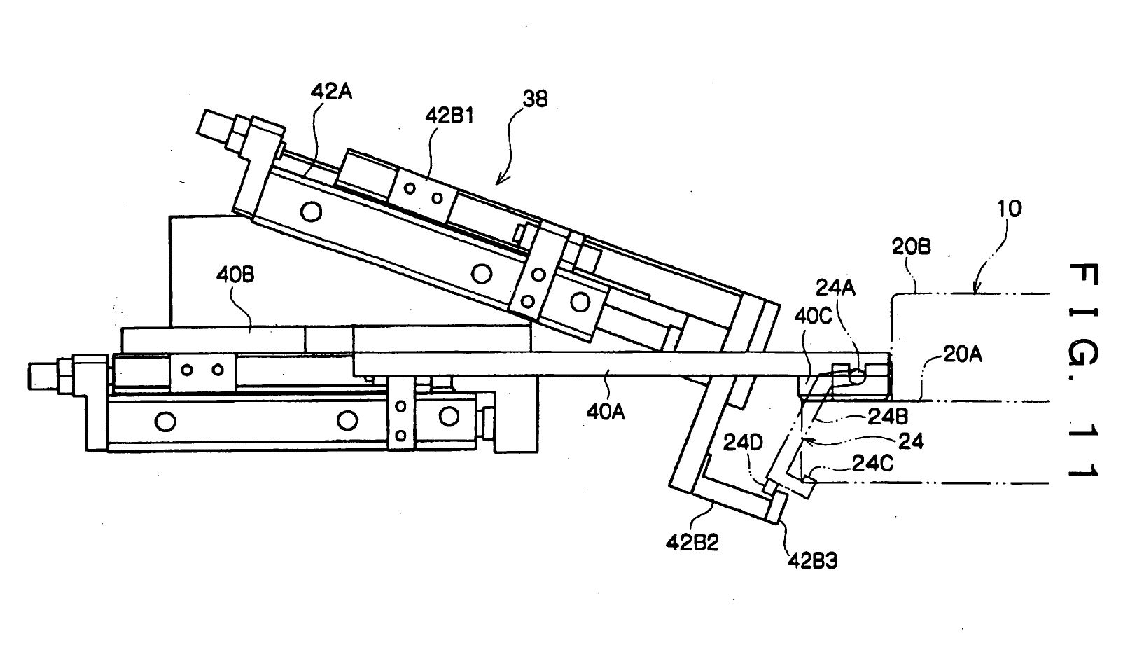

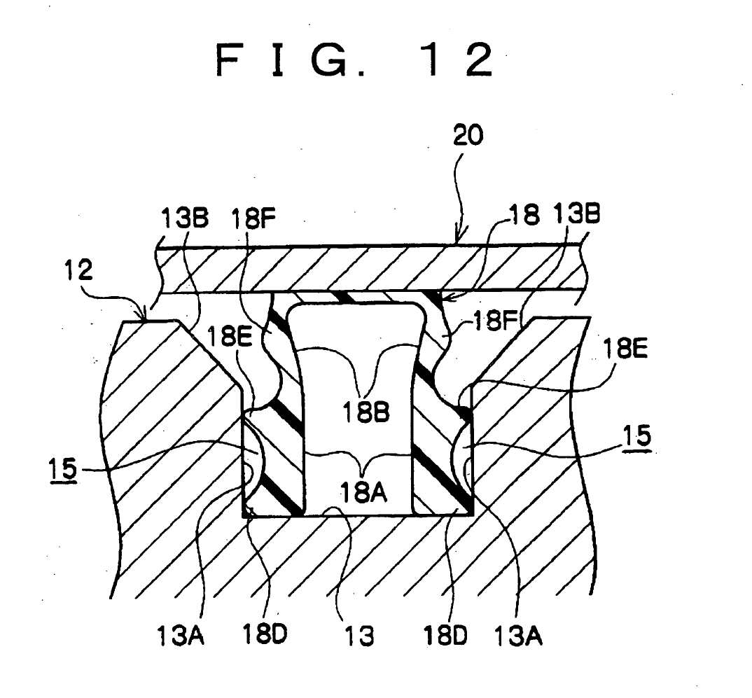

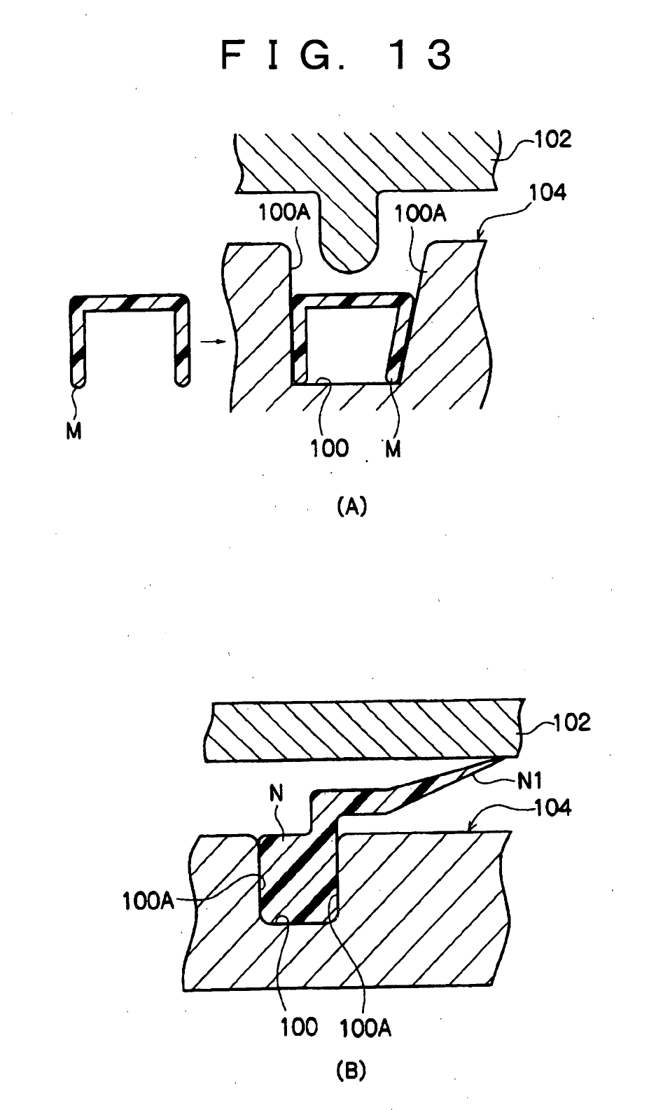

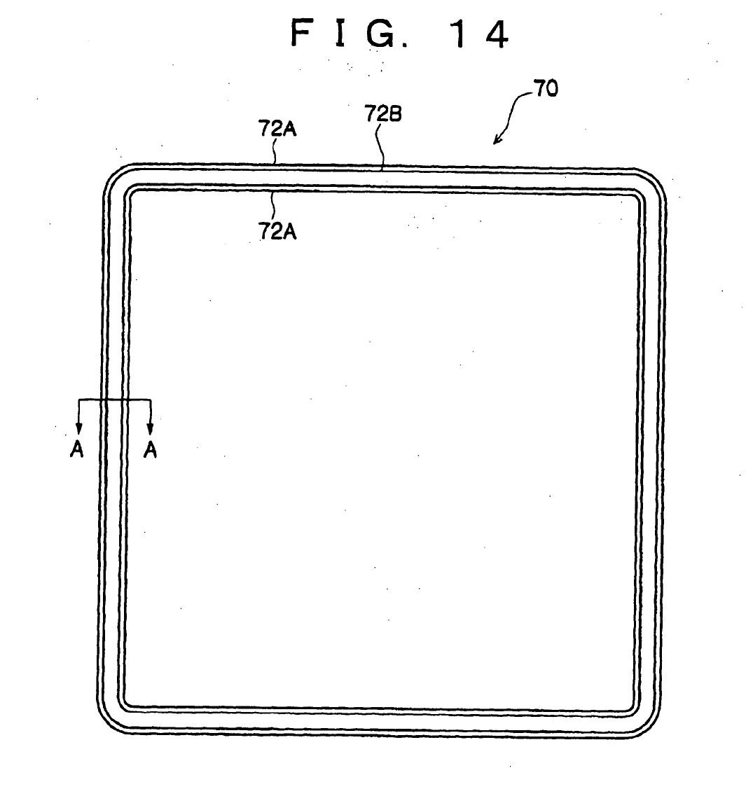

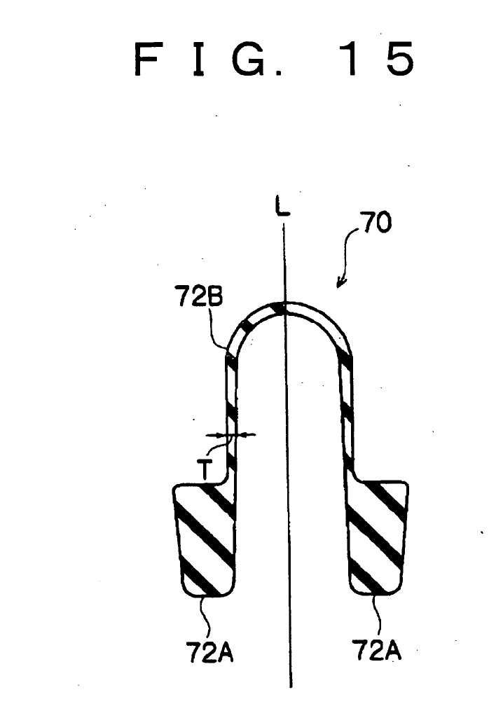

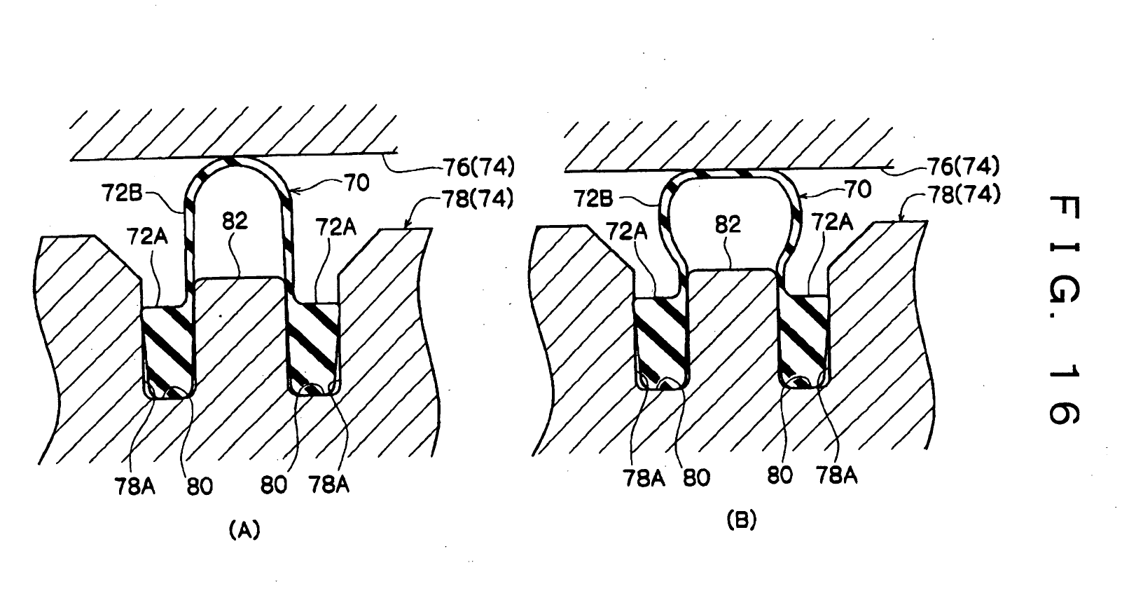

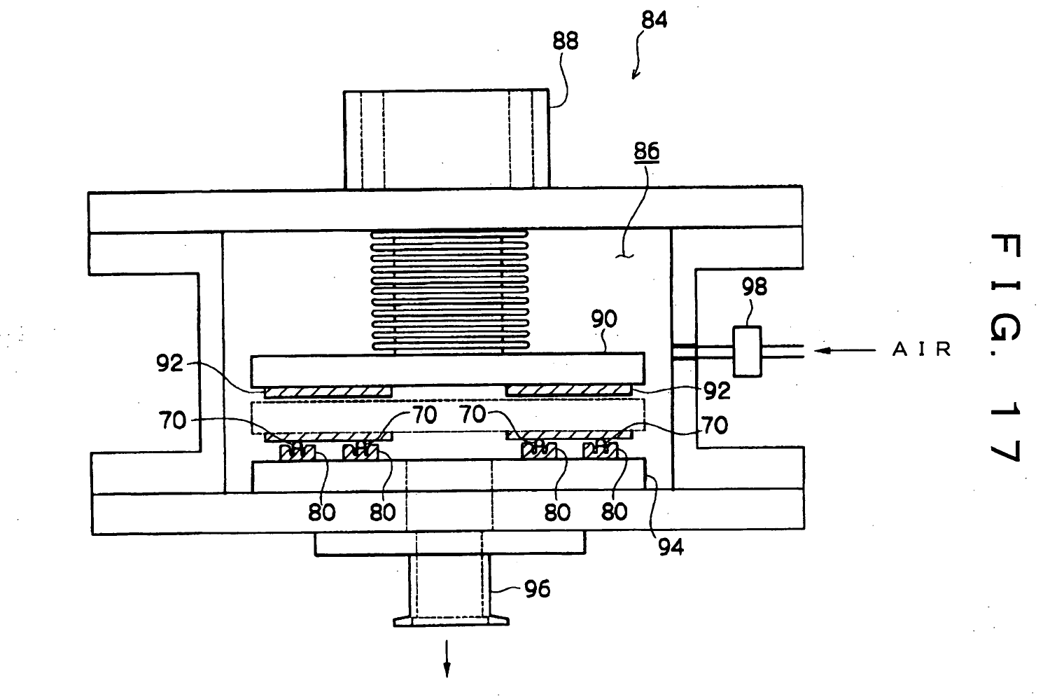

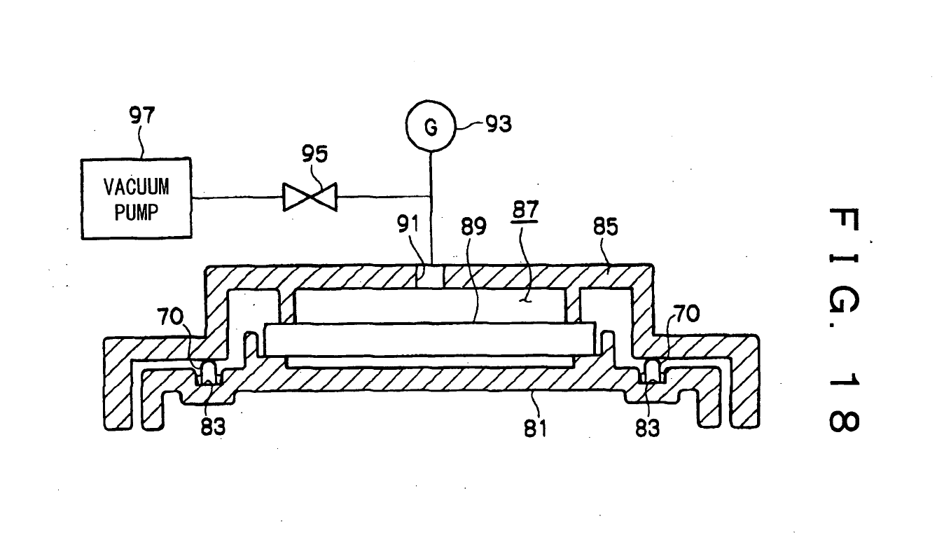

### BRIEF DESCRIPTION OF DRAWINGS

[FIG. 1] A perspective view of a reticle storage case according to a first embodiment of the present invention, which is viewed from diagonally above.

[FIG. 2] A perspective view of the reticle storage case according to the first embodiment of the present invention, which is viewed from diagonally under.

[FIG. 3] An exploded assembly view of the reticle storage case according to the first embodiment of the present invention.

[FIG. 4] A cross-sectional view of a sealing member used for the reticle storage case according to the first embodiment of the present invention.

[FIG. 5] (A): A cross-sectional view showing a state where the sealing member used for the reticle storage case according to the first embodiment of the present invention is disposed in a groove formed in a bottom member, and (B): a cross-sectional view showing a state where a cover member is in contact with the sealing member to press the sealing member.

[FIGS. 6] (A), (B), (C): Cross-sectional views of sealing members as modification examples of the sealing member used for the reticle storage case according to the first embodiment of the present invention.

[FIG. 7] A perspective view of a reticle management apparatus according to the first embodiment of the present invention.

[FIG. 8] A perspective view of a reticle transfer apparatus included in the reticle management apparatus according to the first embodiment of the present invention.

[FIG. 9] A perspective view of an engagement release member included in the reticle transfer apparatus according to the first embodiment of the prevent invention.

[FIG. 10] A view showing a state before a hook member is released by the engagement release member included in the reticle transfer apparatus according to the first embodiment of the present invention.

[FIG. 11] A view showing a state after the hook member is released by the engagement release member included in the reticle transfer apparatus according to the first embodiment of the present invention.

[FIG. 12] A cross-sectional view showing elastic deformation of the sealing member when the engagement of a claw portion and a bottom of the bottom member is released.

[FIGS. 13] (A) and (B): Cross-sectional views showing a state when a conventional sealing member is fitted in a groove.

[FIG. 14] A plane view showing a modification example of the sealing member used for the reticle storage case according to the first embodiment of the present invention.

[FIG. 15] A cross-sectional view taken along the A-A line in FIG. 14.

[FIG. 16] (A): A cross-sectional view showing a state where the modification example of the sealing member used for the reticle storage case according to the first embodiment of the present invention is disposed in the groove formed in the bottom member, and (B): a cross-sectional view showing a state where the cover member comes in contact with the modification example of the sealing member to press the sealing member.

[FIG. 17] A view showing the configuration of a testing machine used for a particle resistance test.

[FIG. 18] A view showing the configuration of a testing machine used for a sealing performance test.

### EXPLANATION OF CODES

10 reticle storage case (glass substrate storage case)
12 bottom member (member)
13 groove
13A sidewall of groove
13B opening edge of groove
14 support member
16 positioning member
18 sealing member
18A pressure portion
18C bent portion
18D first overhanging portion (overhanging portion)
18E second overhanging portion (overhanging portion)
18F projection
20 cover member (member)
24 hook member
24A shaft
24B claw portion
30 reticle management apparatus
32 reticle transfer apparatus
34 first clean room
34A sidewall (first partition member)
44A sidewall (second partition member)
36 lift platform (lift member)
38 engagement release member
40 pressing head
40C buffer member (elastic member)
42 support arm (release/support portion)
44 second clean room
46 first window (first opening)
48 second window (second opening)
50 arm member
52 third clean room
54 first opening/closing shutter device (first opening/closing member)
56 second opening/closing shutter device (second opening/closing member)
58 base member
60 standby room
62 stock room
64 carrier platform (transport means)
66 rail member (transport means)
70 sealing member
72A pressure portion
72B thin portion
74 reticle storage case (glass substrate storage case)
76 cover member
78 bottom member
80 groove
82 salient portion
R reticle
S stepper case

### BEST MODE FOR CARRYING OUT THE INVENTION

Next, a glass substrate storage case, a glass substrate transfer apparatus, a glass substrate management apparatus, and a glass substrate distribution method according to a first embodiment of the present invention will be described with reference to the drawings. Examples of a glass substrate are a reticle, a photomask, and the like, and the reticle is taken as an example of the glass substrate in the description below. Therefore, in the description below, it is assumed that the glass substrate storage case is a reticle storage case, the glass substrate transfer apparatus is a reticle transfer apparatus, the glass substrate management apparatus is a reticle management apparatus, and a glass substrate distribution method is a reticle distribution method.

First, the reticle storage case for reticle storage will be described.

As shown in FIG. 1 to FIG. 3, a reticle storage case 10 has a square bottom member 12. Support members 14 for supporting a square reticle R are provided in the vicinities of respective corners of the bottom member 12 to extend vertically upward. By these four support members 14, the reticle R is supported while being apart from the bottom member 12. Further, from each of the support members 14, a positioning member 16 that is in contact with side faces of the reticle R supported by the support members 14 extends vertically upward. Consequently, the reticle R is positioned by the positioning members 16 while being supported by the support members 14.

A groove 13 (see FIG. 5) is formed near an outer edge of the bottom member 12, and a sealing member 18 is disposed in the groove 13. As shown in FIG. 4, the whole sealing member 18, when loaded with no pressure, is in a reversed V-shape. Specifically, the sealing member 18 is composed of: pressure portions 18A, 18A that have a relatively large thickness and press side faces 13A of the groove 13 when inserted in the groove 13; connection portions 18B, 18B connected to the pressure portions 18A, 18A; and a bent portion 18C having a relatively small thickness and connecting the connection portions 18B, 18B.

Since the sealing member 18 is formed to become gradually thicker from the bent portion 18C toward each of the pressure portions 18A, 18A, the pressure portions 18A, 18A are formed to be relatively thick and are thicker than the bent portion 18C. By thus forming the sealing member 18 to become gradually thicker from the bent portion 18C toward each of the pressure portions 18A, 18A, areas from the bent portion 18C to the pressure portions 18A, 18A can be made smooth and can be free of a stress concentrated portion, which can prevent strength deterioration of the sealing member 18, leading to improved durability thereof. In this manner, the sealing member 18 is formed laterally symmetrical with respect to a center line L in a cross sectional view.

On ends of the pressure portions 18A, 18A, first overhanging portions (overhanging portions) 18D, 18D overhanging outward are formed respectively. Further, near the first overhanging portions 18D, 18D, second overhanging portions (overhanging portions) 18E, 18E overhanging outward similarly to the first overhanging portions 18D, 18D are formed. Further, on the connection portions 18B, 18B, projections 18F, 18F projecting outward are formed respectively.

When a later-described cover member 20 is overlaid on the bottom member 12, the bent portion 18C comes in contact with the cover member 20 to elastically deform due to pressure from the cover member 20.

To fit the sealing member 18 in the groove 13 formed in the bottom member 12, the pressure portions 18A, 18A are inserted into the groove 13 in a state where the pressure portions 18A, 18A are pressed against a resilient force thereof and thus the distance therebetween is reduced, as shown in FIG. 4 and FIG. 5(A). When the pressure portions 18A, 18A are inserted into the groove 13, the pressing force acting on the pressure portions 18A, 18A is released. Consequently, the pressure portions 18A, 18A deform so as to widen the distance therebetween due to the resilient force thereof, so that the first overhanging portions 18D, 18D and the second overhanging portions 18E, 18E provided on the pressure portions 18A, 18A come in contact with the sidewalls 13A, 13A respectively, whereby predetermined pressures act on the sidewalls 13A, 13A from the pressure portions 18A, 18A. In this manner, disposing the sealing member 18 in the groove 13 results in a state where the pressure portions 18A, 18A press the respective sidewalls 13A, 13A. As a result, it is possible to prevent the sealing member 18 from coming off the groove 13 and further to stabilize the posture of the sealing member 18 in the groove 13.

When the sealing member 18 is disposed in the groove 13, gaps 15 are made between the pressure portions 18A, 18A and the sidewalls 13A, 13A of the groove 13, but especially owing to the contact of the second overhanging portions 18E, 18E with the sidewalls 13A, 13A of the groove 13, it is possible to prevent foreign substances such as water and dusts from entering the gaps 15 during a cleaning process of the reticle storage case 10. As a result, corrosion of the sealing member 18 can be prevented.

Further, since the projections 18F, 18F are formed on the respective connection portions 18B, 18B included in the sealing member 18, it is possible to easily hold the sealing member 18 by gripping the projections 18F, 18F. This can improve easiness in handling the sealing member 18. In particular, since an opening edge 13B of the groove 13 formed in the bottom member 12 is chamfered so as to widen an opening of the groove 13, the opening edge 13B of the groove 13 does not obstruct the fitting of the sealing member 18 in the groove 13 and it is possible to easily fit the sealing member 18 in the groove 13 while gripping the projections 18F, 18F. As a result, fittability of the sealing member 18 in the groove 13 can be greatly improved.

In particular, though a conventional sealing member M shown in FIG. 13(A) is fitted along sidewalls 100A of a groove 100, a pressure acting on the sidewalls 100A of the groove 100 from the sealing member M is small, and therefore, when a cover member 102 is overlaid on a bottom member 104 and thereafter is detached, the sealing member M sometimes comes off the groove 100. A conventional sealing member N shown in FIG. 13(B) has a problem that sufficient sealability cannot be ensured even when a support piece N1 comes in contact with the cover member 102, due to low stiffness of a tip of the support piece N1. On the other hand, the sealing member 18 of the present invention solves all the problems of the both in the above respects and realizes a great improvement in fittability in the groove 13 and sealability between the cover member 20 and the bottom member 12.

Incidentally, the sealing member 18 is made of thermoplastic resin having relatively high plasticity (for example, polyester elastomer resin, “Nubelan” manufactured by Teijin Chemicals Ltd., and the like). However, the material of the sealing member 18 is not limited to the thermoplastic resin but may be an elastomer material such as ordinary fluororubber.

The reticle storage case 10 has the cover member 20. The cover member 20 is made of transparent conductive resin. The cover member 20 is composed of a cover base 20A formed in a square shape in a plane view and a cover member main body 20B formed integrally on an upper side of the cover base 20A and formed in a square shape in a plane view. The cover base 20A and the cover member main body 20B are formed to be hollow. Further, the cover member main body 20B is formed so as to be positioned on an inner side of the cover base 20A. In other words, the cover base 20A protrudes outward from the cover member main body 20B. The cover base 20A has recessed portions 22L, 22R in opposite two sides thereof.

On the recessed portions 22L, 22R of the cover member 20, provided are hook members 24 hooked to the bottom member 12 to maintain the state where the cover member 20 is overlaid on the bottom member. Each of the hook members 24 is composed of a shaft 24A and a claw portion formed integrally with the shaft 24A. The shaft 24A is rotatably supported by bearings 26 integrally formed on the cover base 20A. The claw portion 24B is structured to cover a side portion of the cover base 20A when the cover member 20 is overlaid on the bottom member 12. A catch portion 24C engaged with a bottom of the bottom member 12 is formed at a tip of each of the claw portions 24B. In the vicinity of the tip of each of the claw portions 24B, engaging pieces 24D engaged with a later-described protruding portion 42B3 are further formed.

Incidentally, the cover member 20 and the bottom member 12 of the reticle storage case 10 are made of resin such as polycarbonate.

The structure in which the groove 13 is formed in the bottom member 12 and the sealing member 18 is disposed in the groove 13 is taken as an example of the structure of the reticle storage case 10 of this embodiment, but it should be noted that this structure is not restrictive, and an example of another possible structure is to form a groove (not shown) in the cover member 20, instead of forming it in the bottom member 12 or as well as forming it in the bottom member 12, and to dispose the sealing member(s) 18 in the groove(s).

The shape of the sealing member 18 is not limited to that shown in FIG. 4, but to realize appropriate sealability according to a material of the sealing member 18, the sealing member 18 may be formed to have the pressure portions 18A, 18A having a square cross section without any gap between the pressure portions 18A, 18A and the sidewalls 13A of the groove 13, for example, as shown in FIG. 6(A). Another possible structure is to form only the first overhanging portions 18D, 18D on the pressure portions 18A, 18A (omit the second overhanging portions 18E, 18E) as shown in FIG. 6(B), and still another possible structure is to make the connection portions 18B themselves project outward as shown in FIG. 6(C).

Considering the use in transport by air, the reticle storage case 10 of this embodiment may have a breather valve (not shown) with a chemical filter to adjust pressure inside and outside the reticle storage case 10. Providing the breather valve with the chemical filter allows air to flow into the reticle storage case 10 through the breather valve with the chemical filter when external atmospheric pressure is low, which can realize the adjustment of the pressure inside and outside the reticle storage case 10. At this time, even when an ambient environment around the reticle storage case 10 is bad, for example, even when ammonium sulfide ((NH₄)₂SO₄), ammonia (HN₃), sulphate ion (SO₄²⁻), or styrene (C₈H₈) on the order of several ppb exists in the atmosphere, they can be removed by the chemical filter. As a result, it is possible to prevent the occurrence of haze on a surface of the reticle or an adverse effect on a pellicle.

Next, the operation of the reticle storage case 10 according to this embodiment and a reticle distribution method using the reticle storage case 10 will be described.

As shown in FIG. 1 to FIG. 3, the reticle R is placed on the support members 14 formed on the bottom member 12. At this time, the reticle R is supported while being apart from the bottom member 12. When the reticle R is placed on the support members 14, side faces of the reticle R come in contact with the positioning members 16, so that the reticle R is positioned on the support members 14. Consequently, the reticle R cannot freely move on the support members 14, which can prevent the reticle R from coming off the support members 14.

After the reticle R is supported on the support members 14 and positioned by the positioning members 16, the cover member 20 is overlaid on the bottom member 12 from above. In a state where the cover member 20 is in contact with the bottom member 12, the shafts 24A rotate, and along with the rotation of the shafts 24A, the claw portions 24B rotate. Then, the catch portions 24C formed at the tips of the claw portions 24B are engaged with the bottom of the bottom members 12. By the hook members 24 hooked to the bottom of the bottom member 12, it is possible to maintain the state where the cover member 20 is overlaid on the bottom member 12, which can prevent the cover member 20 from coming off the bottom member 12.

When the cover member 20 is overlaid on the bottom member 12, a space portion (not shown) is formed between the cover member 20 and the bottom member 12 since the cover base 20A and the cover member main body 20B constituting the cover member 20 are both hollow. The reticle R supported by the support members 14 is positioned in the space portion. At this time, since the sealing member 18 provided in the bottom member 12 is in contact with the cover member 20, the sealing member 18 separates the space portion and the outside of the cover member 20.

Specifically, as shown in FIG. 5(B), when the cover member 20 is overlaid on the bottom member 12, the bent portion 18C constituting the sealing member 18 comes in contact with the cover member 20 to elastically deform, and therefore, there exists no gap between the sealing member 18 and the cover member 20 and between the sealing member 18 and the bottom member 12, resulting in great improvement in sealability of the space portion. This can ensure airtightness of the space portion and thus no dust adheres to the reticle R housed in the reticle storage case 10, which can prevent quality deterioration of the reticle R.

Moreover, owing to the relatively small thickness of the bent portion 18C, the pressure acting on the cover member 20 from the bent portion 18C can be made small. This can prevent the breakage of the cover member 20 even if the cover member 20 is made of a specific material (for example, resin).

Further, the relatively large thickness of the pressure portions 18A, 18A improves stiffness of the pressure portions 18A, 18A, so that the deformation of the pressure portions 18A, 18A can be inhibited when the pressure acts on the bent portion 18C from the cover member 20. This can prevent the pressure portions 18A, 18A from sliding on the sidewalls 13A, 13A of the groove 13 and thus no frictional force occurs between the pressure portions 18A, 18A and the sidewalls 13A, 13A of the groove 13, which can prevent damages such as cracks of the pressure portions 18A, 18A.

Further, owing to the shape of the sealing member 18 laterally symmetrical with respect to the center line L, a substantially equal pressure acts on places of the bent portion 18C from the cover member 20 when the cover member 20 is overlaid on the bottom member 12. This can prevent a frictional force between a specific portion of the bent portion 18C and the cover member 20 from becoming large, so that the damage of the bent portion 18C can be prevented.

Further, owing to the shape of the sealing member 18 laterally symmetrical with respect to the center line L, the cover member 20 first comes in contact with a peak of the bent portion 18C constituting the sealing member 18 when the cover member 20 comes in contact with the sealing member 18, as shown in FIG. 5(B), and the sealing member 18 expands equally to right and left as the sealing member 18 receives a pressing force from the cover member 20, whereby a sealing surface between the cover member 20 and the sealing member 18 is formed. As a result, irrespective of the degree of the pressing force from the cover member 20, the sealing surface (contact surface) between the cover member 20 and the sealing member 18 does not slide, which can prevent the occurrence of particles due to the friction on the sealing surface.

Further, since the cover member 20 is made of the transparent conductive resin, the reticle R housed inside can be easily seen from the outside of the reticle storage case 10, and in addition, the conductive resin as the material of the cover member 20 makes dusts and the like easily adhere to the cover member 20, which can prevent the dusts from swirling in the space portion and thus can surely prevent the adhesion of the dusts and the like to the reticle R.

To take out the reticle R from the reticle storage case 10, the cover member 20 is pressed against the bottom member 12. When the cover member 20 is pressed against the bottom member 12, the bent portion 18C further elastically deforms to reduce the relative distance between the cover member 20 and the bottom member 12, so that the engagement between the claw portions 24B and the bottom of the bottom member 12 is released.

Next, after the engagement of the claw portions 24B and the bottom of the bottom member 12 is released, the shafts 24A constituting the hook members 24 rotate, and along with the rotation of the shafts 24A, the claw portions 24B also rotate. In this state, the cover member 20 can be detached from the bottom member 12 and the reticle R housed inside can be taken out.

As described above, the reticle storage case 10 of the present invention can exhibit an extremely excellent effect in view of preventing quality deterioration of the reticle R because the structure can be simplified, the reticle R can be stored in the airtight state, and the reticle R can be easily taken out.

Next, a reticle distribution method using the reticle storage case 10 of the present invention will be described.

Having high sealability, the reticle storage case 10 of the present invention allows the reticle R to be taken out of the clean room. Via the reticle storage case 10, the reticle R can be sequentially distributed from a reticle manufacturer manufacturing the reticle R to a pattern plotter forming a predetermined pattern on the reticle R, and further from the pattern plotter to a device maker projecting/transferring the pattern on the reticle R onto semiconductor wafers, and the like, so that only the reticle storage case 10 of the single type need to be prepared. Therefore, the respective makers and traders are free from the need to separately prepare storage cases for storing the reticle R.

Further, the use of the above-described reticle storage case 10 for storing the reticle R eliminates a need for sticking a tape or the like on the reticle storage case 10 for improved airtightness of the reticle R, which has been conventionally necessary. Therefore, since there is no need to peel off the tape or the like stuck on the reticle storage case 10 when the reticle R is taken out, dusts and so on do not swirl inside the reticle storage case 10, which can prevent quality deterioration of the reticle R.

Next, a reticle transfer apparatus and a reticle management apparatus of the present invention will be described in detail.

As shown in FIG. 7 to FIG. 11, a reticle management apparatus 30 includes a reticle transfer apparatus 32. The reticle transfer apparatus 32 includes a first clean room 34. The first clean room 34 is in a cuboid shape and is formed by an upper wall 34U, a lower wall 34E, and four sidewalls 34A, 34B, 34C, 34D so that an inner space thereof becomes airtight. A board-shaped lift platform (lift member) 36 is disposed inside the first clean room 34. A driving mechanism (not shown, a lift member) is connected to the lift platform 36, and the lift platform 36 is movable up and down when driven by the driving mechanism. The upper wall 34U has an opening and the lift platform 36, when lifted, is positioned in the opening. Thus, the lift platform 36 constitutes part of the upper wall 34U.

Two engagement release members 38 are attached to the upper wall 34U of the first clean room 34 so as to face each other. As shown in FIG. 9 to FIG. 11, each of the engagement release members 38 includes: a pressing head (pressing portion) 40 pressing the cover member 20 against the bottom member 12; and a support arm (release/support portion) 42 that is engaged with the claw portion 24B constituting the hook member 24 attached to the cover member 20 to rotate the claw portion 24B together with the shaft 24A and supports the cover member 20.

The pressing head 40 is provided to be movable in a horizontal direction and a vertical direction. The pressing head 40 includes two pressing pieces 40A, 40A, a base member 40B to which the pressing pieces 40A, 40A are attached. Further, buffer members (elastic members) 40C, 40C made of an elastic material such as rubber are attached to tips of the pressing pieces 40A, 40A. In accordance with the horizontal movement of the pressing head 40, the pressing pieces 40A, 40A also move in the horizontal direction, and in accordance with the vertical movement of the pressing head 40, the pressing pieces 40A, 40A also move in the vertical direction.

The support arm 42 includes: a tilting platform 42A provided on the base member 40B; and a support arm main body 42B moving on the tilting platform 42A in a tilting direction. The support arm main body 42B includes a sliding portion 42B1 moving on the tilting platform 42A and an engagement/support portion 42B2 attached to an end of the sliding portion 42B1. The protruding portion 42B3 engaged with the engaging pieces 24D formed in the claw portion 24B is also formed at the tip of the engagement/support portion 42B2.

One sidewall (first partition member) 34A constituting the first clean room 34 to separate the first clean room 34 from a later-described second clean room 44 has a first window 46 in a rectangular shape.

The second clean room 44 is connected to the first clean room 34. The second clean room 44 is formed in a cuboid shape and is formed by an upper wall 44U, a lower wall 44E, and four sidewalls 44A, 44B, 44C, 44D so that an inner space thereof becomes airtight. Incidentally, a common sidewall serves as the sidewalls 34A of the first clean room 34 and the sidewall (first partition member) 44C of the second clean room 44.

The second clean room 44A is provided with a first opening/closing shutter device (first opening/closing member) 54 opening/closing the first window 46. The first opening/closing shutter device 54 includes an opening/closing shutter main body 54A in a flat plate shape opening/closing the first window 46 and a driving portion 54B moving the opening/closing shutter main body 54A up and down.

The sidewall (second partition member) 44A constituting the second clean room 44 and facing the sidewall 44C similarly has a second window 48. The second clean room 44 is similarly provided with a second opening/closing shutter device (second opening/closing member) 56 opening/closing the second window 48. The second opening/closing shutter device 56 includes an opening/closing shutter main body 56A in a flat plate shape opening/closing the second window 48 and a driving portion 56B moving the opening/closing shutter main body 56A up and down.

A control part (not shown) controls the driving of the first opening/closing shutter device 54 and the second opening/closing shutter device 56.

An arm member 50 is disposed in the second clean room 44. The arm member 50 transfers the reticle R supported on the bottom member 12 constituting the reticle storage case 10 placed on the lift platform 36 to a bottom member S2 constituting a stepper case S placed on a base main body 58A, and is composed of a support board (arm member) 50A supporting the reticle R and a link mechanism (arm member) 50B moving the support board 50A from the inside of the first clean room 34 to the inside of the third clean room 52 as well as in the vertical direction.

The third clean room 52 is connected to the second clean room 44. The third clean room 52 is formed in a cuboid shape, and is formed by an upper wall 52U, a lower wall 52E, and four sidewalls 52A, 52B, 52C, 52D so that an inner space thereof becomes airtight. A common sidewall serves as the sidewall 44A of the second clean room 44 and the sidewall (second partition member) 52C of the third clean room 52.

A base member 58 is disposed in the third clean room 52. The base member 58 includes the base main body 58A in a flat plate shape on which various kinds of stepper cases are placed. A driving mechanism (not shown, a base member) is connected to the base main body 58A and the base main body 58A is capable of moving in the vertical direction when driven by the driving mechanism.

A preferable example of the structure of the stepper case S is such that it is constituted of a cover member 20 and a bottom member 12 similarly to the reticle storage case 10 and is capable of storing the reticle R by overlaying the cover member 20 on the bottom member 12.

An opening is formed in the upper wall 52U, and the base main body 58A in a lifted state is positioned in the opening. In this manner, the base main body 58A constitutes part of the upper wall 52U.

The reticle management apparatus 30 includes a standby room 60 connected to the reticle transfer apparatus 32. The standby room 60 is connected to the first clean room 34, and is defined by an upper wall 60U and four sidewalls 60A, 60B, 60C, 60D. A common sidewall serves as the sidewall 34D of the first clean room 34 and the sidewall 60B of the standby room 60.

Under a floor on which the reticle transfer apparatus 32 is disposed, a stock room 62 is disposed. The stock room 62 is to store the reticles R of a plurality of kinds in a state where they are housed in the reticle storage cases 10. The standby room 60 and the stock room 62 communicate with each other via an opening 61 formed in the floor.

Further, a rail part (transport means) 66 extends from the standby room 60 to the stock room 62, and a carrier platform (transport means) 64 moving in the vertical direction on the rail part 66 is disposed on the rail part 66. The carrier platform 64 is driven by a predetermined driving mechanism (not shown, a transport means).

Next, the operation of the reticle transfer apparatus 32 and the reticle management apparatus 30 of this embodiment will be described.

As shown in FIG. 7 to FIG. 11, a reticle storage case 10 housing a predetermined reticle R is selected from the stock room 62 to be placed on the carrier platform 64. After the reticle storage case 10 is placed on the carrier platform 64, the driving mechanism operates to move up the carrier platform 64 along the rail part 66. Consequently, the carrier platform 64 is moved to the standby room 60 from the stock room 62 and in due time is positioned on the upper wall 60U constituting the standby room 60.

The reticle storage case 10 positioned on the upper wall 60U constituting the standby room 60 is placed on the lift platform 36 positioned on the upper wall 34U of the first clean room 34. After the reticle storage case 10 is placed on the lift platform 36, the pressing heads 40 move in the horizontal direction, so that the two pressing pieces 40A, 40A of each of the pressing heads 40 are positioned on the cover base 20A. In the state where the pressing pieces 40A, 40A are positioned on the cover base 20A, the pressing heads 40 move down to press the cover member 20 against the bottom member 12. At this time, since the pressing pieces 40A, 40A come in contact with the cover base 20A via the buffer members 40C, 40C, no breakage or the like is caused to the cover base 20A. Further, as shown in FIG. 12, when the cover member 20 is pressed against the bottom member 12, the bent portion 18C constituting the sealing member 18 elastically deforms to reduce the relative distance between the cover member 20 and the bottom member 12. Consequently, the claw portions 24B constituting the hook members 24 and the bottom of the bottom member 12 are disengaged. After the disengagement of the claw portions 24B and the bottom of the bottom member 12, the support arm main bodies 42B that have slid on the tilting platforms 42A to move downward move up on the tilting platforms 42A, and then the protruding portions 42B3 of the engagement/support portions 42B2 are engaged with the engaging pieces 24D formed in the claw portions 24B in due time. When the support arm main bodies 42B move up on the tilting platforms 42A in a state where the protruding portions 42B3 are engaged with the engaging pieces 24D, the claw portions 24B rotate along with the rotation of the shafts 24A to become open. In the state where the claw portions 24B are open, the cover member 20 is supported by the support arm main bodies 42B. This results in a state where only the bottom member 12 is placed on the lift platform 36.

Next, the lift platform 36 on which the bottom member 12 is placed is moved down. At this time, the first window 46 and the second window 48 are kept closed by the first opening/closing shutter device 54 and the second opening/closing shutter device 56 respectively. Therefore, no air flow occurs inside the first clean room 34, which can prevent the adhesion of dusts and the like to the reticle R placed on the bottom member 12. When the lift platform 36 moves down, the opening/closing shutter main body 54A constituting the first opening/closing shutter device 54 is driven by the driving portion 54B, so that the first window 46 is opened. After the first window 46 is opened, the support board 50A is moved by the link mechanism 50B to enter the first clean room 34 from the second clean room 44 through the first window 46. Then, the support board 50A is moved to a position under the reticle R that is supported while being a certain distance apart from the bottom member 12, and thereafter, is moved up by the link mechanism 50B. Consequently, the reticle R is supported by the support board 50A. After the reticle R is supported by the support board 50A, the support board 50A moves again to the second clean room 44 from the first clean room 34.

After the support board 50A moves from the first clean room 34 to the second clean room 44, the opening/closing shutter main body 54A constituting the first opening/closing shutter device 54 is driven by the driving portion 54B, so that the first window 46 is closed. After the first window 46 is closed by the first opening/closing shutter device 54, the opening/closing shutter main body 56A constituting the second opening/closing shutter device 56 is driven by the driving portion 56B, so that the second window 48 is opened. Thus opening the second window 48 after the first window 46 is closed causes no air flow into the first clean room 34, so that dusts and the like do not swirl in the first clean room 34.

After the second window 48 is opened, the support board 50A supporting the reticle R is moved by the link mechanism 50B to enter the third clean room 52 through the second window 48. After the support board 50A enters the third clean room 52, the reticle R is placed on the bottom member S2 constituting the stepper case S (a case specialized for each stepper) placed on the base main body 58A that has been kept on standby. After the reticle R is placed on the bottom member S2 constituting the stepper case S, the base main body 58A moves up to be positioned on the upper wall 52U of the third clean room 52. After the base main body 58A is positioned on the upper wall 52U of the third clean room 52, the cover member S1 is put thereon, so that the reticle R is housed in the stepper case S. In this manner, the reticle R is transferred from the reticle storage case 10 to the stepper case S.

After the reticle R is transferred from the reticle storage case 10 to the stepper case S, the opening/closing shutter main body 56A constituting the second opening/closing shutter 56 is driven by the driving portion 56B, so that the second window 48 is closed.

After a predetermined reticle R is transferred to the stepper case S, this reticle is used in a stepper (not shown) by a device maker. In the stepper (not shown), a predetermined pattern formed on the reticle R is projected/transferred onto semiconductor wafers.

Next, the operation in which the reticle R having been used in the stepper is replaced in the reticle storage case 10 will be described.

The reticle R that has been used in the stepper is placed on the base main body 58A while kept placed on the bottom member S2 of the stepper case S, and the base main body 58A is driven by the driving mechanism (not shown) to move down in the third clean room 52.

Next, the opening/closing shutter main body 56A constituting the second opening/closing shutter device 56 is driven by the driving portion 56B, so that the second window 48 is opened. After the second window 48 is opened, the support board 50A is moved by the link mechanism 50B to enter the third clean room 52 from the second clean room 44 through the second window 48. Then, the support board 50A is moved to a position under the reticle R that is supported with a certain distance away from the bottom member 12, and thereafter, is moved up by the link mechanism 50B. Consequently, the reticle R is supported by the support board 50A. After the reticle R is supported by the support board 50A, the support board 50A moves again to the second clean room 44 from the third clean room 52. At this time, the first window 46 is kept closed.

After the support board 50A supporting the reticle R moves from the third clean room 52 to the second clean room 44, the opening/closing shutter main body 56A constituting the second opening/closing shutter device 56 is driven by the driving portion 56B to close the second window 48 and at the same time, the opening/closing shutter main body 54A constituting the first opening/closing shutter device 54 is driven by the driving portion 54B to open the first window 46.

After the first window 46 is opened, the support board 50A is moved by the link mechanism 50B to enter the first clean room 34 from the second clean room 44 through the first window 46. Then, the reticle R is placed on the bottom member 12 on the lift platform 36 that has been moved down inside the first clean room 34 and has been kept on standby. At this time, the reticle R is placed on and supported by the support members 14 and positioned by the positioning members 16. Consequently, the reticle R is transferred from the stepper case S to the reticle storage case 10.

After the reticle R is placed on the bottom member 12, the support board 50A is moved by the link mechanism 50B to return to the second clean room 44 from the first clean room 34 through the first window 46, and then the first window 46 is closed.

After the reticle R is placed on the bottom member 12, the lift platform 36 moves up inside the first clean room 34, and the bottom member 12 is fitted to the cover member 20 supported by the support arm main body 42B, and then the cover member 20 is fixed to the bottom member 12 by the hook members 24. Consequently, the reticle R is housed in the reticle storage case 10. After the reticle R is housed in the reticle storage case 10, the reticle storage case 10 is placed on the carrier platform 64 to be stored in a predetermined place of the stock room 62.

As described above, according to the reticle transfer apparatus 32 and the reticle management apparatus 30 of the present invention, the transfer work of the reticle R is performed in each of the clean rooms 34, 44, 52, so that the adhesion of dusts and so on to the reticle R can be prevented, which can prevent quality deterioration of the reticle R.

Moreover, near the reticle transfer apparatus 32, the stock room 62 is provided to individually store the plural reticles R which are housed in the reticle storage cases 10, so that it is possible to quickly and easily take out a necessary reticle R from the stock room 62 when the reticle R needs to be transferred by the reticle transfer apparatus 32 from the reticle storage case 10 to the stepper case S.

Since the stock room 62 is formed under the floor on which the reticle transfer apparatus 32 is installed, an underfloor space can be effectively used. Storing an enormous number of the reticles R in a clean room would require the expansion of the space of the clean room and greatly higher management and maintenance cost, but storing the reticles R in the stock room 62 formed underfloor as in the present invention can greatly reduce the maintenance and management cost of the reticles R and allows effective use of a vacant space of the clean room for other purposes.

Further, the stepper need not be provided with a library for storing the reticles R, which can realize downsizing of the stepper and a great reduction in manufacturing cost of the stepper.

Another possible method is to assign ID numbers exclusively for the reticles R housed in the reticle storage cases 10 and for the reticle storage cases 10, determine whether the both ID numbers match each other by a determining apparatus (not shown, a determining means), and display the determination result on a monitor (not shown, a display means) or the like. Consequently, a user can instantaneously determine whether or not the reticle R and the reticle storage case 10 match each other only by checking the monitor. As a result, the reticles R can be stored in a state where the reticles R and the reticle storage cases 10 correspond to each other, which can enhance a function of managing the reticles R.

Next, a modification example of the reticle storage case and the sealing member according to the first embodiment of the present invention will be described.

As shown in FIG. 14 and FIG. 15, a sealing member 70 being a modification example is formed hollow, and is continuously formed so as to be in a substantially square shape in a plane view. The sealing member 70 includes a pair of pressure portions 72A and a thin portion 72B connecting the pressure portions 72A, 72A to each other. Here, each of the pressure portions 72A, 72A is formed to become gradually thinner from a rear end toward a tip thereof. An upper side of the thin portion 72B comes in contact with a cover member 76 of a later-described reticle storage case 74 (see FIG. 16) and is formed in a curved shape. A thickness T of the thin portion 72B is not less than 0.2 mm nor more than 0.6 mm, and is preferably 0.3 mm. Further, the sealing member 70 is formed laterally symmetrical with respect to a center line L extending in a height direction of a cross section taken along the thickness direction of the sealing member 70.

The sealing member 70 is made of an elastomer material (rubber) such as fluororubber. As the fluororubber, perfluoro fluororubber (FFKM) with a completely fluorinated main chain, ordinary fluororubber (FKM) in which carbon-hydrogen bond exists in part of a main chain, fluorine thermoplastic elastomer that can be extrusion-molded, and the like are preferable because they have high heat resistance and generate only a small amount of gas.

As shown in FIG. 16, a groove 80 is formed near an outer edge of a bottom member 78 constituting the reticle storage case 74 being the modification example. A salient portion 82 is formed in a groove widthwise center portion of the groove 80. The other structure of the reticle storage case 74 is the same as the structure of the reticle storage case according to the above-described first embodiment, and therefore, description thereof will be omitted. Incidentally, the reticle storage case 74 is made of resin such as polycarbonate.

Next, a description will be given of the operation when the sealing member 70 being the modification example is fitted in the bottom member 78 of the reticle storage case 74. As shown in FIG. 16(A), the pressure portions 72A, 72A of the sealing member 70 are fitted in the groove 80 to sandwich the salient portion 82 formed in the groove 80. At this time, the sealing member 70 can be easily inserted in the groove 80 since each of the pressure portions 72A, 72A becomes thinner from the rear end toward the tip thereof. In a state where the sealing member 70 is fitted in the groove 80, the rear ends of the pressure portions 72A, 72A give a predetermined pressure as a reactive force to groove sidewalls 78A, 78A groove-widthwisely facing the salient portion 82. This can prevent the sealing member 70 from coming off the groove 80 and can prevent a cleaning liquid from entering the inside of the groove 80 at the time of the cleaning or the like of the reticle storage case 74.

Next, a description will be given of the operation when the cover member 76 of the reticle storage case 74 is fixed to the bottom member 78. As shown in FIG. 16(B), when the cover member 76 is overlaid on the bottom member 78 and is pushed downward in this state, the thin portion 72B of the sealing member 70 elastically deforms to expand in the groove width direction. Consequently, a space portion can be kept airtight because an upper side of the sealing member 70 is in contact with the cover member 76 with a predetermined reactive force acting thereon. Further, since the sealing member 70 is formed laterally symmetrical with respect to the center line L, the thin portion 72B slides little on the cover member 76 when the thin portion 72B comes in contact with the cover member 76, which can effectively reduce the occurrence of particles.

Further, since the thin portion 72B is made of rubber and the thickness T thereof is not less than 0.2 mm nor more than 0.6 mm, airtightness in the space portion can be ensured and a compression reactive force acting on the cover member 76 from the thin portion 72B can be reduced, which can prevent the occurrence of warp or the like of the cover member 76. Thus, it is possible to realize both sure airtightness of the space portion and the prevention of the occurrence of warp or the like of the cover member 76.

On the contrary, if the thickness of the thin portion is more than 0.6 mm, the compression reactive force acting on the cover member or the bottom member from the thin portion becomes large, which results in a problem that the warp or the like of the cover member or the bottom member easily occurs. If the thickness of the thin portion is less than 0.2 mm, the thin portion itself only has insufficient stiffness and repulsion, so that the compression reactive force acting on the cover member or the bottom member becomes too small, which poses a problem that airtightness of the space portion cannot be ensured.

Next, a description will be given of a test for testing particle resistance of the sealing member being the modification example. As shown in FIG. 17, a pressing member 90 that moves up and down by pneumatic pressure from a pneumatic cylinder 88 was provided in an inner space 86 of a testing machine 84, and resin plates 92 made of the same material as that of the cover member 76 of the reticle storage case 74 were pasted on the pressing member 90. Further, a table 94 was provided on a bottom of the inner space 86, four grooves 80 that are the same as the groove 80 formed in the bottom member 78 of the reticle storage case 74 were provided in an upper surface of the table 94, and the sealing members 70 being the above-described modification example were fitted in the grooves 80 respectively. Then, the pneumatic cylinder 88 was operated ten thousand times, thereby causing the resin plates 92 to press the sealing members 70. At this time, the sealing members 70 were compressively deformed only by about 1.5 mm after the resin plates 92 came in contact with the sealing members 70, and thereafter, the resin plates 92 were lifted up to release the elastic deformation of the sealing members 70, which operations were repeated ten thousand times. Particles occurring at this time were led to the outside through a supply path 96 provided on the bottom of the inner space 86, and the number of the particles was measured by a suction-type particle counter (not shown, a suction amount 2.83 L/min). Incidentally, air was supplied to the inner space 86 via a 0.01 μm filter 98.

This test was conducted under the same condition in the following states: a state where the inventions were fitted, namely, the sealing members 70 being the modification example were fitted in the grooves 80; a state where no sealing member was fitted in the grooves 80; and a state where the conventional sealing members N shown in FIG. 13(B) were fitted in the grooves 80.

Here, to form the sealing member 70 being the modification example used in this test, fluororubber (vinylidene fluoride/hexafluoropropyrene/tetrafluoroethyrene-ternary fluororubber: G921 manufactured by DAIKIN), a crosslinking agent, a filler such as carbon black were mixed and kneaded by an open roll to produce a rubber compound. The rubber compound was filled in a die and was crosslinked and molded by heating at 165° C. for 15 minutes, and thereafter, was subjected to secondary vulcanization at 180° C. for 12 hours, whereby the sealing member was molded.

The results of the test for testing the particle resistance are shown in the following table 1.

TABLE 1

| PARTICLE | | | | | | A TOTAL(THE |
|---|---|---|---|---|---|---|
| SIZE (μm) | 0.1 | 0.15 | 0.2 | 0.3 | 0.5 | NUMBER) |
| NO SEALING | 59 | 2 | 2 | 2 | 1 | 66 |
| MEMBER | | | | | | |
| FITTED | | | | | | |
| INVENTIONS | 63 | 2 | 1 | 0 | 0 | 66 |
| FITTED | | | | | | |
| CONVENTIONAL | 632 | 566 | 519 | 417 | 131 | 2265 |
| PRODUCTS | | | | | | |
| FITTED | | | | | | |

As shown in the above table 1, the number of particles occurring in the state where the inventions are fitted is 66, but the number of particles occurring in the state where no sealing member is fitted is also 66, which has proved that the number of particles occurring from the sealing members is close to substantially zero level. On the other hand, the number of particles occurring in the state where the conventional product is fitted is 2265, which has proved that the use of the sealing member being the present invention can greatly reduce the particles, compared with the use of the conventional sealing member.

Next, a description will be given of a test for testing sealing performance of the sealing member being the modification example. As shown in FIG. 18, a receiving member 81 was used as a member corresponding to the bottom member 78 of the reticle storage case 74, a groove 83 was formed in the receiving member 81, and the sealing member 70 being the modification example was fitted therein. Then, a covering member 85 was used as a member corresponding to the cover member 76 of the reticle storage case 74, the covering member 85 was overlaid on the receiving member 81 so as to set an inner space portion 87 airtight. A glass substrate 89 is disposed in the inner space portion 87. A through path 91 was formed in the covering member 85, and a negative pressure gauge 93, a pressure control valve 95, and a vacuum pump 97 were connected to the through path 91. In this test, the pressure control valve 95 was opened and the vacuum pump 97 was operated to evacuate the pressure in the space portion 87 to about −500 Pa, and thereafter, the pressure in the space portion 87 was measured by the negative pressure gauge 93 while the pressure control valve 95 was kept closed. The measurement by the negative pressure gauge 95 after the pressure evacuation of the space portion 87 to about −500 Pa by the operation of the vacuum pump 97 was conducted totally twice, that is, immediately after the pressure control valve 95 was closed and one week later.

The results of the test for testing the sealing performance are shown in the following table 2.

TABLE 2

| | IMMEDIATELY AFTER | ONE WEEK LATER |
|---|---|---|
| PRESSURE(Pa) | −490 | −485 |

As shown in the above table 2, it has been proved that the use of the sealing member 70 of the present invention makes it possible to maintain the pressure in the space portion 87 substantially constant.

The results of the above two tests have proved that according to the sealing member 70 of the present invention, it is possible to reduce the occurrence of particles and to ensure sealability of the space portion, that is, particle resistance and sealability can be both achieved.

What is claimed is:

1. A glass substrate storage case for storing a glass substrate, comprising:
a bottom member on which the glass substrate is placed;
a cover member overlaid on said bottom member so as to cover the glass substrate placed on said bottom member and to form a space portion between said bottom member and said cover member;
a sealing member provided in said bottom member and/or said cover member to keep the space portion airtight in a state where said cover member is overlaid on said bottom member; and
a hook member provided on said cover member and hooked to said bottom member to maintain the state where said cover member is overlaid on said bottom member.

2. The glass substrate storage case according to claim 1, wherein said hook member has: a shaft rotatably provided on said cover member; and a claw portion rotating with respect to the shaft as a rotation axis to be engaged with a bottom portion of said bottom member.

3. The glass substrate storage case according to claim 1 or 2,
wherein said sealing member is disposed in a groove formed in said cover member and/or said bottom member,
wherein said sealing member has: a pair of pressure portions inserted in the groove to press sidewalls of the groove; and a bent portion connecting the pressure portions and coming in contact with said cover member or said bottom member to elastically deform when said cover member is overlaid on said bottom member, and
wherein a thickness of the pressure portions is larger than a thickness of the bent portion.

4. The glass substrate storage case according to claim 3, wherein projections are provided on at least part of areas from the bent portion to the pressure portions.

5. The glass substrate storage case according to claim 4, wherein thickness gradually becomes larger from the bent portion toward the pressure portions.

6. The glass substrate storage case according to claim 1 or 2,
wherein a groove having a salient portion is formed in said cover member and/or said bottom member,
wherein said sealing member is made of rubber, and
wherein said sealing member has: a pair of pressure portions inserted in the groove so as to sandwich the salient portion and pressing groove sidewalls facing the salient portion; and a thin portion which connects the pressure portions and whose portion that comes in contact with said cover member or said bottom member when said cover member is overlaid on said bottom member is formed in a curved shape and elastically deforms by coming in contact with said cover member or said bottom member when said cover member is overlaid on said bottom member.

7. The glass substrate storage case according to claim 6, wherein a thickness of the thin portion is not less than 0.2 mm nor more than 0.6 mm.

8. The glass substrate storage case according to claim 6 or 7, wherein a thickness of each of the pressure portions gradually becomes smaller toward a tip portion that is in contact with a bottom of the groove.

9. The glass substrate storage case according to any one of claims 6 to 8, wherein said sealing member is formed symmetrical with respect to a center line extending in a height direction of a cross section taken along a thickness direction of said sealing member.

10. A glass substrate transfer apparatus transferring a glass substrate stored in the glass substrate storage case according to any one of claims 1 to 9 into another stepper case, the apparatus comprising:
a lift member which is movable up/down and on which said glass substrate storage case is placed;
an engagement release member releasing the hooking of the hook member to the bottom member of the glass substrate storage case placed on said lift member and supporting the cover member from under;
a base member on which the stepper case is placed; and
an arm member taking out, from the bottom member, the glass substrate placed on the bottom member on said lift member to move the glass substrate to the stepper case side.

11. The glass substrate transfer apparatus according to claim 10, wherein said engagement release member includes: a pressing portion pressing the cover member against the bottom member to elastically deform the sealing member, thereby releasing the engagement of the claw member and the bottom member; and a release/support portion lifting the claw portion disengaged from the bottom member while rotating the claw portion with respect to the shaft, and supporting the cover member.

12. A glass substrate management apparatus managing glass substrates, the apparatus comprising:
the glass substrate transfer apparatus according to claim 10 or 11; and
a stock room formed under a floor on which the glass substrate transfer apparatus is installed

13. A glass substrate distribution method, wherein by using the glass substrate storage case according to any one of claims 1 to 9, the glass substrate is distributed from a glass substrate maker manufacturing the glass substrate to a pattern plotter forming a predetermined pattern on the glass substrate and further from the pattern plotter to a device maker projecting/transferring the pattern on the glass substrate onto a semiconductor wafer.

14. A sealing member made of an elastic material and fitted in a groove formed in a joint surface between members, the sealing member comprising:
a pair of pressure portions pressing sidewalls of the groove when the sealing member is fitted in the groove; and a bent portion connecting said pair of pressure portions to each other,
wherein, to fit the sealing member in the groove, a distance between said pressure portions is reduced.

15. The sealing member according to claim 14, wherein a thickness of the sealing member gradually becomes larger from said bent portion toward said pressure portions

16. The sealing member according to claim 14 or 15, wherein projections are provided on at least part of areas between said bent portion and said pressure portions.

17. A sealing member made of rubber and fitted in a groove formed in a joint surface between members so as to sandwich a salient portion of the groove, the sealing member comprising:
a pair of pressure portions pressing groove sidewalls facing the salient portion while the sealing member is inserted in the groove; and a thin portion which connects said pressure portions and whose portion that comes in contact with one or the other of the members is formed in a curved shape and elastically deforms by coming in contact with one or the other of the members.

18. The sealing member according to claim 17, wherein a thickness of said thin portion is not less than 0.2 mm nor more than 0.6 mm.

19. The sealing member according to claim 17 or 18, wherein each of said pressure portions gradually becomes thinner toward a tip portion that is in contact with a bottom of the groove.

20. The sealing member according to any one of claims 17 to 19, the sealing member being formed symmetrical with respect to a center line extending in a height direction of a cross section taken along a thickness direction of the sealing member.

21. A sealing structure for realizing sealing by the sealing member according to any one of claims 14 to 20 fitted in the groove,
wherein an opening edge of the groove is chamfered so as to widen an opening of the groove.
